(19) United States
(12) Patent Application Publication
(10) Pub. No.: US 2013/0153980 A1
(43) Pub. Date: Jun. 20, 2013

(54) NONVOLATILE SEMICONDUCTOR MEMORY DEVICE AND METHOD OF MANUFACTURING THE SAME

(71) Applicant: Masashi HONDA, Mie-ken (JP)

(72) Inventor: Masashi HONDA, Mie-ken (JP)

(21) Appl. No.: 13/708,073

(22) Filed: Dec. 7, 2012

(30) Foreign Application Priority Data
Dec. 9, 2011 (JP) 2011-270169

(51) Int. Cl. H01L 21/02; H01L 27/088

(52) U.S. Cl. CPC H01L 21/02697; H01L 27/088
USPC 257/316; 438/593

(57) ABSTRACT

A nonvolatile semiconductor storage device manufacturing method including forming a gate insulating film, a first silicon film, an inter-electrode insulating film, a second silicon film, and a processing insulating film on a semiconductor substrate; embedding an inter-gate insulating film between the gate electrodes of the memory cell transistors and the selector gate transistors; detaching the processing insulating film to expose an upper surface of the second silicon film, and processing the inter-gate insulating film so that an upper surface of the inter-gate insulating film is substantially at the same level as the upper surface of the second silicon film; exposing an upper portion of the second silicon film by etching the inter-gate insulating film between the gate electrodes of two adjacent ones of the selector gate transistors down to a first depth while leaving a contact region of a first width between the gate electrodes; performing silicidation of the upper portion of the second silicon film of each of the gate electrodes; and forming an inter-layer insulating film after the silicidation.

### CROSS-REFERENCE TO RELATED APPLICATIONS

This application is based upon and claims the benefit of priority from the prior Japanese Patent Application No. 2012-003013, filed Dec. 9, 2011, the entire contents of which are incorporated herein by reference.

### FIELD

Embodiments of the present invention relate to a nonvolatile semiconductor storage device manufacturing method and a nonvolatile semiconductor storage device.

### BACKGROUND

In order to reduce wiring resistance in a word line connecting gate electrodes of memory cell transistors, nonvolatile semiconductor storage devices employ a configuration in which silicide films are provided in upper portions of the control gate electrodes. There is a technique of forming a silicide film by forming a polycrystalline silicon film as a control gate electrode and then by performing silicidation of the upper portion of the polycrystalline silicon film.

Such a silicidation method includes etching down an inter-gate insulating film so that the upper portion of the polycrystalline silicon film to be the control gate electrode can be exposed by a predetermined depth. Here, there is a level difference between a top surface of the control gate electrode and a top surface of the inter-gate insulating film. The following silicidation process makes the polycrystalline silicon expand when turning into silicide, and thus the level difference increases.

The level difference thus produced is not preferable if it remains in later steps such as contact opening step for forming a contact and damascene metal step, because the level difference may cause variations in wiring resistance. Accordingly, the following steps are performed: forming a silicon nitride film or the like on the top surface; forming a silicon oxide film or the like for offsetting the level difference; flattening the resultant structure by chemical mechanical polishing (CMP) with the silicon nitride film used as the mask, and forming the inter-layer insulating film on the resultant structure.

However, after such a level difference is produced, the silicon nitride film cannot be formed at a high temperature because the silicidation has been performed. Thus, the silicon nitride film might not be dense enough. Hence, the CMP is likely to make scratches using the silicon nitride film as a stopper film. As a result, it may affect the electrical characteristics.

### BRIEF DESCRIPTION OF THE DRAWINGS

FIG. 1 is a diagram schematically showing an electrical configuration of a part of a memory cell region of a NAND flash memory device of a first embodiment;

FIG. 2 is a plan view schematically showing a partial structure of the memory cell region;

FIG. 3A is a schematic vertical cross sectional view taken along the line A-A in FIG. 2;

FIG. 3B is a schematic vertical cross sectional view taken along the line B-B in FIG. 2;

FIG. 4A is a vertical cross sectional view taken along the line A-A in FIG. 2 and schematically showing a manufacturing phase;

FIG. 4B is a vertical cross sectional view taken along the line B-B in FIG. 2 and schematically showing a manufacturing phase;

FIG. 5A is a vertical cross sectional view taken along the line A-A in FIG. 2 and schematically showing a manufacturing phase;

FIG. 5B is a vertical cross sectional view taken along the line B-B in FIG. 2 and schematically showing a manufacturing phase;

FIG. 6A is a vertical cross sectional view taken along the line A-A in FIG. 2 and schematically showing a manufacturing phase;

FIG. 6B is a vertical cross sectional view taken along the line B-B in FIG. 2 and schematically showing a manufacturing phase;

FIG. 7A is a vertical cross sectional view taken along the line A-A in FIG. 2 and schematically showing a manufacturing phase;

FIG. 7B is a vertical cross sectional view taken along the line B-B in FIG. 2 and schematically showing a manufacturing phase;

FIG. 8A is a vertical cross sectional view taken along the line A-A in FIG. 2 and schematically showing a manufacturing phase;

FIG. 8B is a vertical cross sectional view taken along the line B-B in FIG. 2 and schematically showing a manufacturing phase;

FIG. 9A is a vertical cross sectional view taken along the line A-A in FIG. 2 and schematically showing a manufacturing phase;

FIG. 9B is a vertical cross sectional view taken along the line B-B in FIG. 2 and schematically showing a manufacturing phase;

FIG. 10A is a vertical cross sectional view taken along the line A-A in FIG. 2 and schematically showing a manufacturing phase;

FIG. 10B is a vertical cross sectional view taken along the line B-B in FIG. 2 and schematically showing a manufacturing phase;

FIG. 11A is a vertical cross sectional view taken along the line A-A in FIG. 2 and schematically showing a manufacturing phase;

FIG. 11B is a vertical cross sectional view taken along the line B-B in FIG. 2 and schematically showing a manufacturing phase;

FIG. 12A is a vertical cross sectional view taken along the line A-A in FIG. 2 and schematically showing a manufacturing phase;

FIG. 12B is a vertical cross sectional view taken along the line B-B in FIG. 2 and schematically showing a manufacturing phase;

FIG. 13A is a vertical cross sectional view taken along the line A-A in FIG. 2 and schematically showing a manufacturing phase;

FIG. 13B is a vertical cross sectional view taken along the line B-B in FIG. 2 and schematically showing a manufacturing phase;

FIG. 14A is a vertical cross sectional view taken along the line A-A in FIG. 2 and schematically showing a manufacturing phase;

FIG. 14B is a vertical cross sectional view taken along the line B-B in FIG. 2 and schematically showing a manufacturing phase;

FIG. 15A is a schematic vertical cross sectional view of a second embodiment taken along the line A-A in FIG. 2;

FIG. 15B is a schematic vertical cross sectional view of the second embodiment taken along the line B-B in FIG. 2;

FIG. 16A is a vertical cross sectional view taken along the line A-A in FIG. 2 and schematically showing a manufacturing phase;

FIG. 16B is a vertical cross sectional view taken along the line B-B in FIG. 2 and schematically showing a manufacturing phase;

FIG. 17A is a vertical cross sectional view taken along the line A-A in FIG. 2 and schematically showing a manufacturing phase;

FIG. 17B is a vertical cross sectional view taken along the line B-B in FIG. 2 and schematically showing a manufacturing phase;

FIG. 18A is a vertical cross sectional view taken along the line A-A in FIG. 2 and schematically showing a manufacturing phase;

FIG. 18B is a vertical cross sectional view taken along the line B-B in FIG. 2 and schematically showing a manufacturing phase;

FIG. 19A is a vertical cross sectional view taken along the line A-A in FIG. 2 and schematically showing a manufacturing phase;

FIG. 19B is a vertical cross sectional view taken along the line B-B in FIG. 2 and schematically showing a manufacturing phase;

FIG. 20A is a vertical cross sectional view taken along the line A-A in FIG. 2 and schematically showing a manufacturing phase;

FIG. 20B is a vertical cross sectional view taken along the line B-B in FIG. 2 and schematically showing a manufacturing phase;

FIG. 21A is a schematic vertical cross sectional view of a third embodiment taken along the line A-A in FIG. 2;

FIG. 21B is a schematic vertical cross sectional view of the third embodiment taken along the line B-B in FIG. 2;

FIG. 22A is a vertical cross sectional view taken along the line A-A in FIG. 2 and schematically showing a manufacturing phase;

FIG. 22B is a vertical cross sectional view taken along the line B-B in FIG. 2 and schematically showing a manufacturing phase;

FIG. 23A is a vertical cross sectional view taken along the line A-A in FIG. 2 and schematically showing a manufacturing phase;

FIG. 23B is a vertical cross sectional view taken along the line B-B in FIG. 2 and schematically showing a manufacturing phase;

FIG. 24A is a vertical cross sectional view taken along the line A-A in FIG. 2 and schematically showing a manufacturing phase;

FIG. 24B is a vertical cross sectional view taken along the line B-B in FIG. 2 and schematically showing a manufacturing phase;

FIG. 25A is a vertical cross sectional view taken along the line A-A in FIG. 2 and schematically showing a manufacturing phase;

FIG. 25B is a vertical cross sectional view taken along the line B-B in FIG. 2 and schematically showing a manufacturing phase;

FIG. 26A is a schematic vertical cross sectional view of a fourth embodiment taken along the line A-A in FIG. 2;

FIG. 26B is a schematic vertical cross sectional view of the fourth embodiment taken along the line B-B in FIG. 2;

FIG. 27A is a vertical cross sectional view taken along the line A-A in FIG. 2 and schematically showing a manufacturing phase;

FIG. 27B is a vertical cross sectional view taken along the line B-B in FIG. 2 and schematically showing a manufacturing phase;

FIG. 28A is a vertical cross sectional view taken along the line A-A in FIG. 2 and schematically showing a manufacturing phase;

FIG. 28B is a vertical cross sectional view taken along the line B-B in FIG. 2 and schematically showing a manufacturing phase;

FIG. 29A is a schematic vertical cross sectional view of a fifth embodiment taken along the line A-A in FIG. 2;

FIG. 29B is a schematic vertical cross sectional view of the fifth embodiment taken along the line B-B in FIG. 2;

FIG. 30A is a vertical cross sectional view taken along the line A-A in FIG. 2 and schematically showing a manufacturing phase;

FIG. 30B is a vertical cross sectional view taken along the line B-B in FIG. 2 and schematically showing a manufacturing phase;

FIG. 31A is a vertical cross sectional view taken along the line A-A in FIG. 2 and schematically showing a manufacturing phase;

FIG. 31B is a vertical cross sectional view taken along the line B-B in FIG. 2 and schematically showing a manufacturing phase;

FIG. 32A is a vertical cross sectional view taken along the line A-A in FIG. 2 and schematically showing a manufacturing phase;

FIG. 32B is a vertical cross sectional view taken along the line B-B in FIG. 2 and schematically showing a manufacturing phase;

FIG. 33A is a vertical cross sectional view taken along the line A-A in FIG. 2 and schematically showing a manufacturing phase;

FIG. 33B is a vertical cross sectional view taken along the line B-B in FIG. 2 and schematically showing a manufacturing phase;

FIG. 34A is a vertical cross sectional view taken along the line A-A in FIG. 2 and schematically showing a manufacturing phase;

FIG. 34B is a vertical cross sectional view taken along the line B-B in FIG. 2 and schematically showing a manufacturing phase;

FIG. 35A is a vertical cross sectional view taken along the line A-A in FIG. 2 and schematically showing a manufacturing phase;

FIG. 35B is a vertical cross sectional view taken along the line B-B in FIG. 2 and schematically showing a manufacturing phase;

FIG. 36A is a vertical cross sectional view taken along the line A-A in FIG. 2 and schematically showing a manufacturing phase;

FIG. 36B is a vertical cross sectional view taken along the line B-B in FIG. 2 and schematically showing a manufacturing phase;

FIG. 37A is a vertical cross sectional view taken along the line A-A in FIG. 2 and schematically showing a manufacturing phase;

FIG. 37B is a vertical cross sectional view taken along the line B-B in FIG. 2 and schematically showing a manufacturing phase;

FIG. 38A is a vertical cross sectional view taken along the line A-A in FIG. 2 and schematically showing a manufacturing phase;

FIG. 38B is a vertical cross sectional view taken along the line B-B in FIG. 2 and schematically showing a manufacturing phase;

FIG. 39A is a vertical cross sectional view taken along the line A-A in FIG. 2 and schematically showing a manufacturing phase;

FIG. 39B is a vertical cross sectional view taken along the line B-B in FIG. 2 and schematically showing a manufacturing phase;

FIG. 40A is a vertical cross sectional view taken along the line A-A in FIG. 2 and schematically showing a manufacturing phase;

FIG. 40B is a vertical cross sectional view taken along the line B-B in FIG. 2 and schematically showing a manufacturing phase;

FIG. 41A is a vertical cross sectional view taken along the line A-A in FIG. 2 and schematically showing a manufacturing phase;

FIG. 41B is a vertical cross sectional view taken along the line B-B in FIG. 2 and schematically showing a manufacturing phase;

FIG. 42A is a vertical cross sectional view taken along the line A-A in FIG. 2 and schematically showing a manufacturing phase;

FIG. 42B is a vertical cross sectional view taken along the line B-B in FIG. 2 and schematically showing a manufacturing phase;

FIG. 43A is a vertical cross sectional view taken along the line A-A in FIG. 2 and schematically showing a manufacturing phase; and

FIG. 43B is a vertical cross sectional view taken along the line B-B in FIG. 2 and schematically showing a manufacturing phase.

### DETAILED DESCRIPTION

A nonvolatile semiconductor storage device manufacturing method according to one embodiment includes: forming a gate insulating film, a first silicon film, an inter-electrode insulating film, a second silicon film, and a processing insulating film on a semiconductor substrate; sequentially etching the processing insulating film, the second silicon film, the inter-electrode insulating film, and the first silicon film to form gate electrodes of memory cell transistors and selector gate transistors; embedding an inter-gate insulating film between the gate electrodes of the memory cell transistors and the selector gate transistors; detaching the processing insulating film to expose an upper surface of the second silicon film, and processing the inter-gate insulating film so that an upper surface of the inter-gate insulating film is substantially at the same level as the upper surface of the second silicon film; exposing an upper portion of the second silicon film by etching the inter-gate insulating film between the gate electrodes of two adjacent ones of the selector gate transistors down to a first depth while leaving a contact region of a first width between the gate electrodes; performing silicidation of the upper portion of the second silicon film of each of the gate electrodes; and forming an inter-layer insulating film after the silicidation.

A nonvolatile semiconductor storage device according to one embodiment includes: a semiconductor substrate; gate electrodes of memory cell transistors and selector transistors each including a first silicon film, an inter-electrode insulating film, a second silicon film, and a silicide film which are formed on the semiconductor substrate with a gate insulating film provided in between; an inter-gate insulating film including an embedded portion formed to be embedded between the gate electrodes of two selector gate transistors up to a level lower than upper surfaces of the gate electrodes, and a higher level portion of a first width embedded between the gate electrodes up to substantially the same level with the upper surfaces of the gate electrodes; an adjustment insulating film formed on an upper surface of the higher level portion of the inter-gate insulating film, wherein a gap is formed between the gate electrodes of the memory cell transistors.

A nonvolatile semiconductor storage device according to another embodiment includes: a semiconductor substrate; gate electrodes of memory cell transistors and selector transistors each including a first silicon film, an inter-electrode insulating film, a second silicon film, and a silicide film which are formed on the semiconductor substrate with a gate insulating film provided in between an inter-gate insulating film including an embedded portion formed to be embedded between the gate electrodes of two selector gate transistors up to a level lower than upper surfaces of the gate electrodes, and a higher level portion of a first width embedded between the gate electrodes up to substantially the same level with the upper surfaces of the gate electrodes; and an adjustment insulating film formed on an upper surface of the higher level portion of the inter-gate insulating film.

### First Embodiment

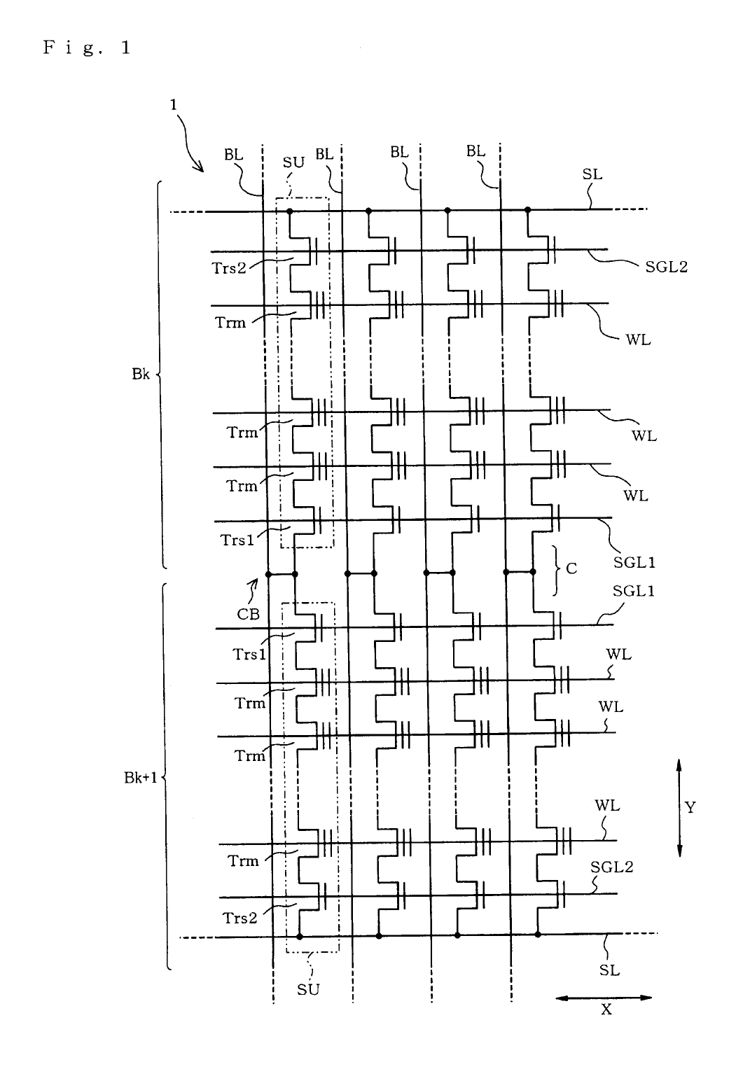

A first embodiment where the present invention is applied to a NAND flash memory is described below with reference to FIG. 1 to FIG. 14. The drawings are not drawn to scale and thus, do not reflect the actual measurements of the features such as the correlation of thickness to planar dimensions and the relative thickness of different layers. The vertical and horizontal directions are relative directions defined assuming that a circuit formation surface side of a semiconductor substrate described later is on the upper side, and thus do not necessarily match with those defined with the gravitational acceleration direction as reference.

First, a configuration of a NAND flash memory device of this embodiment is described. FIG. 1 is a partial equivalent circuit representation of a memory cell array formed in a memory cell region of a NAND flash memory device 1.

In the memory cell array of the NAND flash memory device 1, NAND cell units SU are arranged in rows and columns. The NAND cell units SU each include two select gate transistors Trs1 and Trs2 and a plurality of (e.g., 64) memory cell transistors Trm connected in series between the select gate transistors Trs1 and Trs2. In the NAND cell unit SU, adjacent ones of the plurality of memory cell transistors Trm share the source/drain region.

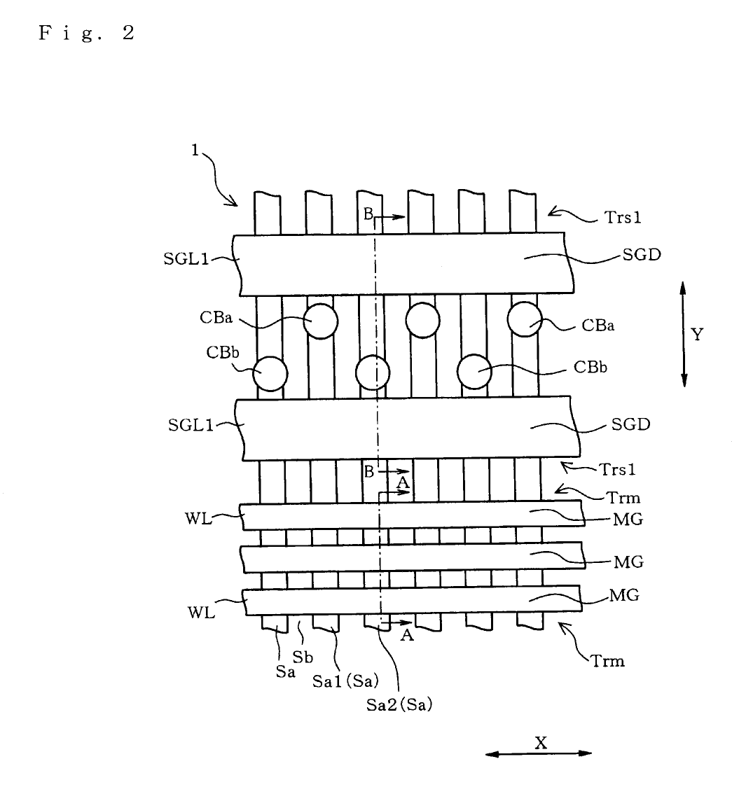

The memory cell transistors Trm aligned in an X direction (word line direction) in FIG. 1 are connected to each other by a common word line WL. The select gate transistors Trs1 aligned in the X direction in FIG. 1 are connected to each other by a common select gate line SGL1, and the select gate transistors Trs2 aligned in the X direction are connected to each other by a common selector gate line SGL2. The drain region of the select gate transistor Trs1 is connected to a bit line contact CB (CBa and CBb in FIG. 2A). The bit line contact CB is connected to a bit line BL extending in a Y direction (bit line direction) orthogonal to the X direction in FIG. 1. The select gate transistor Trs2 is connected to a source line SL extending in the X direction in FIG. 1 through a source region.

FIG. 2 is a partial plan view of a layout pattern of the memory cell region. As shown in FIG. 2, an element isolation region Sb having an STI (shallow trench isolation) structure made by embedding an insulating film in a trench, and extending along the Y direction in FIG. 2 is formed in the memory cell region of a p-type silicon substrate 2 as a semiconductor substrate. A plurality of the element isolation regions Sb are formed along the X direction at a predetermined interval. Thus, a plurality of element regions Sa extending in the Y direction in FIG. 2 and separated from each other are formed along the X direction on a surface portion of the silicon substrate 2.

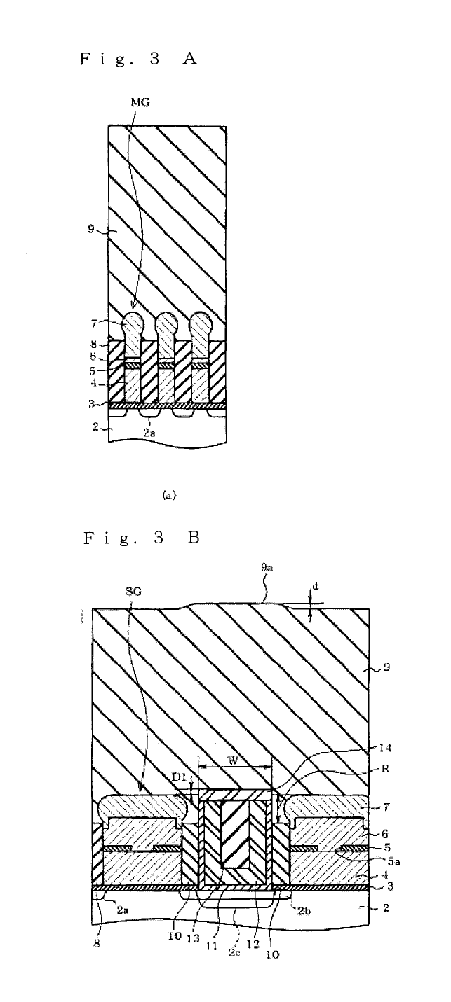

The word line WL extends along the direction (X direction in FIG. 2) orthogonally crossing the element regions Sa. A plurality of the word lines WL are formed along the Y direction in FIG. 2 at a predetermined interval. A gate electrode MG (see FIG. 3A) is formed on a portion of the element region Sa through which the word line WL crosses.

The plurality of memory cell transistors Trm adjacently arranged in the Y direction constitutes a part of a NAND string (memory cell string). The select gate transistors Trs1 and Trs2 are respectively disposed on outer sides in the Y directions of the memory cell transistors Trm at both ends of the NAND string. A plurality of the select gate transistors Trs1 are provided along the X direction, and gate electrodes SG of the plurality of select gate transistors Trs1 are electrically connected to each other by the select gate line SGL1. The gate electrode SG of the select gate transistor Trs1 is formed on a portion of the element region Sa through which the select gate line SGL1 crosses.

Similarly, a plurality of the select gate transistors Trs2 are provided along the X direction, although not shown in the FIGURE. The gate electrodes of the plurality of select gate transistors Trs are electrically connected to each other through the select gate line SGL2. A gate electrode is also formed on a portion of the element region Sa through which the select gate line SGL2 crosses.

The bit line contacts CBa and CBb are formed on first and second element regions Sa1 and Sa2 between the adjacent gate electrodes SG-SG. The bit line contacts CBa and CBb are arranged in a zigzag form with the bit line contacts CBa disposed close to one of the gate electrodes SG and the bit line contacts CBb disposed close to the other one of the gate electrodes SG. The bit contacts CBa and CBb may be disposed in such a manner that the adjacent ones of the bit contacts CBa and CBb are far from one another. Thus, short-circuiting between the bit contacts CBa and CBb is less likely to occur.

FIGS. 3A and 3B each schematically show a cross-sectional structure inside the memory cell region. FIG. 3A shows a cross-sectional structure of the memory cell transistor Trm taken along the line A-A in FIG. 2. FIG. 3B shows a Y direction cross-sectional structure of a portion around a pair of select gate transistors Trs1 and Trs2 and a region between the select transistors Trs1 and Trs2 at which the bit line contact CBb is formed, taken along the line B-B in FIG. 2. In the description given below, the select gate transistor is simply referred to as Trs.

In FIGS. 3A and 3B, a gate insulating film 3 is formed on an upper surface of the silicon substrate 2 as the semiconductor substrate. The gate insulating film 3 is formed on an upper surface of the silicon substrate 2 at a region where the memory cell transistors Trm and the select gate transistors Trs are formed, by using a silicon oxide film for example. The memory cell transistor Trm includes the gate electrode MG formed on the gate insulating film 3 and a source/drain region 2a. A plurality of the memory cell transistors Trm are adjacently formed along the Y direction. A pair of select gate transistors Trs are respectively formed adjacent to those of the memory cell transistors Trm disposed at the ends.

The gate electrode GM of the memory cell transistor Tr includes a polycrystalline silicon film 4 as a first silicon film for forming a floating gate electrode, an inter-electrode insulating film 5, a polycrystalline silicon film 6 as a second silicon film for forming a control gate electrode, and a silicide film 7, that are formed on the gate insulating film 3. The inter-electrode insulating film 5 is an oxide-nitride-oxide (ONO) film, a nitride-oxide-nitride-oxide-nitride (NONON) film, an insulating film having a high dielectric constant, or the like.

The source/drain regions 2a are formed on the surface of the silicon substrate 2 between the gate electrodes MG-MG and between the gate electrodes SG-MG. A lightly doped drain (LDD) region 2b serving as the drain region is formed on the surface of the silicon substrate 2 between the gate electrodes SG-SG. The source/drain region 2a and the LDD region 2b can be formed by introducing impurities in the surface of the silicon substrate 2. A drain region 2c is formed on the surface of the silicon substrate 2 between the gate electrodes SG-SG by introducing an impurity at a high concentration. Thus, the LDD structure is formed.

The gate electrode SG of the select gate transistor Trs has substantially the same structure as the gate electrode MG of the memory cell transistor Trm. Specifically, the polycrystalline silicon film 4, the inter-electrode insulating film 5, the polycrystalline silicon film 6, and the silicide film 7 are stacked on the gate insulating film 3. In the gate electrode SG, an opening 5a is formed at a center portion of the inter-electrode insulating film 5. Thus, the polycrystalline silicon films 4 and 6 are in contact with one another to achieve electrical continuity therebetween. Although not shown, the gate electrodes SG of the select gate transistors Trs1 and Trs2 have the same structure.

The silicide film 7 formed in the upper portion of each of the gate electrode MG and the gate electrode SG is formed by forming a metal film for forming the silicide layer after the polycrystalline silicon film 6 is formed, and by performing heat treatment on the metal film for silicidation of the upper portion of the polycrystalline silicon film 6. Since the silicide film 7 is formed by the silicidation of polycrystalline silicon film 6, the height and the width are slightly larger at the upper portion where the silicidation progresses largely.

The silicidation reaction also progresses from the upper portion and side surfaces of the polycrystalline silicon film 6. Thus, the gate electrode MG has a small width, the silicidation reaction progressing into the lower portion of the polycrystalline silicon film 6. On the other hand, the gate electrode SG has a wide width, the silicidation reaction progressing toward the inner side partially at an end surface portion of the upper portion of the gate electrode SG.

A silicon oxide film 8 as the inter-gate insulating film is embedded between the gate electrodes MG-MG and between the gate electrodes MG-SG. Between the gate electrodes MG, the silicon oxide film 8 has the level of the upper surface around the center of the silicide film 7 in the vertical direction. A silicon oxide film 9 as an interlayer insulating film having a predetermined thickness is formed to cover the resultant structure.

Between the gate electrodes SG-SG and on the side walls of the gate electrodes SG, spacer films 10 are formed. Between the spacer films 10 between the gate electrodes SG-SG, the gate insulating film 3 is detached and the surface of the silicon substrate 2 is exposed. A silicon oxide film 11 formed of TEOS films and a silicon nitride film 12 are formed along the exposed upper surface and along the side surfaces of the spacer films 10, and a silicon oxide film 13 is formed to be embedded in a remaining recess portion.

A portion formed of the silicon oxide film 11, the silicon nitride film 12, and the silicon oxide film 13 has the upper surface being slightly lower than the upper surface of the silicide film 7. A silicon nitride film 14 having a predetermined thickness as an adjustment insulating film is formed on the upper surface of the portion. The silicon nitride film 14 has the upper surface at a level higher than the upper surface of the silicide film 7 by a level difference D1. The difference D1 is the same as or slightly smaller than the thickness of the silicon nitride film 14. The difference D1 is smaller than the thickness of the silicon nitride film 14 because, as will be described later, the gate electrode SG slightly expands by the silicidation reaction for forming the silicide film 7 to reduce the difference the top level of silicon nitride film 14 and that of the gate electrode SG.

The silicon nitride film 14 has a sufficient width W to cover the portion including the silicon oxide film 11, the silicon nitride film 12, and the silicon oxide film 13. The width W may be set in such a manner that a sufficient width can be secured for forming a contact hole in the later step. Thus, the width may be sufficient to cover the silicon oxide film 13 or to even cover a part of the spacer film 10. The width W may be even larger as long as no trouble is caused when the silicide film 7 of the select gate electrode SG is formed.

In the structure described above, the silicon nitride film 14 has the upper surface at the level higher than the upper surface of the silicide film 7 of the gate electrode SG by the level difference D1. Thus, the silicon oxide film 9 formed on the upper surface of the silicide film 7 has on the upper surface, a protrusion 9a with a level difference d (<D1) equal to or smaller than the level difference D1. The level difference of such a level is much less likely to cause trouble in the later steps.

Here, if a conventional structure is employed, in the manufacturing steps, the height of the portion including the silicon oxide film 11, the silicon nitride film 12, and the silicon oxide film 13 in the manufacturing step is substantially the same as that of the silicon oxide films 8 and 10 etched down when the silicide film 7 is formed. Specifically, in FIG. 3B, there is a level difference of a length R. Thus, flattening including an insulating film forming for burying the recess and the CMP has been additionally performed.

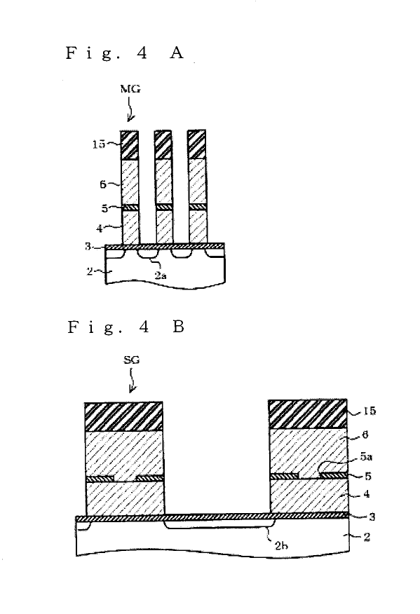

An example of a manufacturing method of the above structure is described with reference to FIG. 4 to FIG. 14. While the description of the embodiment focuses on the features, an additional step may be performed between steps as long as the additional step is not an unusual one, and some steps may be omitted. The order of steps may be changed if practically possible.

Steps for achieving a gate processed state shown in FIGS. 4A and 4B are briefly described. The gate insulating film 3 as a silicon oxide film is formed on the p-type silicon substrate 2. The gate insulating film 3 is formed by thermal oxidation for example. The polycrystalline silicon film 4 as a material for the floating gate electrode is formed by low pressure chemical vapor deposition (LP-CVD). Here, phosphorus (P) that is an n-type impurity or boron (b) that is a p-type impurity is used as the impurity.

Although not elaborated in the figures, trenches dividing the polycrystalline silicon substrate 4 and the upper portion of the silicon substrate 2 in a direction orthogonal to the sheet of FIGS. 4A and 4B are formed by photolithography and etching. The element isolating insulating films (not shown) are embedded in the trenches and thus the element regions Sa and Sc are divided into a plurality, and the element isolation regions Sb and Sd are formed.

The inter-electrode insulating film 5 is formed by forming an ONO film or the like on the polycrystalline silicon film 4 by the LP-CVD. Radical nitridation may be performed before or after the ONO film is formed to form the NONON film, or a high dielectric constant film including aluminum oxide (alumina) and hafnium oxide may be used instead of an intermediate nitride film. A polycrystalline silicon film 6a as a material of the control gate electrode is formed on the inter-electrode insulating film 5 by the CVD. The polycrystalline silicon film 6a has a thickness including that of the silicide film 7 and of the polycrystalline silicon film 6 described in the structure of FIG. 3, and thus is thicker than the polycrystalline silicon film 6. Then, a silicon nitride film 15 as a processing insulating film is formed on the polycrystalline silicon film 6a by the CVD.

A silicon oxide film (not shown) serving as a hard mask in dry etching is formed on the silicon nitride film 15. Using photolithography, a resist film is patterned into a line-and-space pattern in the memory cell region, and into a predetermined pattern in a peripheral circuit region. The silicon oxide film is patterned with the resist film serving as a mask to form a hard mask, and then, anisotropic etching (reactive ion etching (RIE) for example) is performed on the silicon oxide film 15 by using the hard mask.

By performing the anisotropic etching on the polycrystalline silicon film 6, the inter-electrode insulating film 5, and the polycrystalline silicon film 4, the gate electrodes MG and SG separated from each other are formed. In this step, etching reaching an intermediate portion of the gate insulating film 3 or reaching the silicon substrate 2 may be performed to remove the gate insulating film 3. Through a general ion implantation, an n-type impurity (e.g., phosphorous) is introduced into a surface of the silicon substrate 2 by using the silicon nitride films 15 of the gate electrodes MG and SG as the mask. Then, by heating, the source/drain region 2a and the LDD region 2b (as well as the source region) are formed. Thus, the structure as shown in FIGS. 4A and 4B can be obtained.

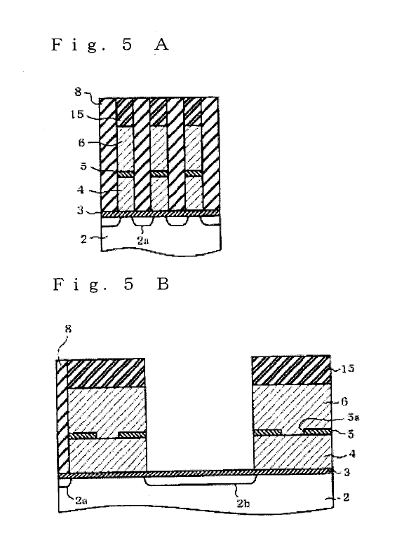

As shown in FIGS. 5A and 5B, the silicon oxide film 8 is formed in an embedded manner between the gate electrodes MG-MG and between the gate electrodes MG-SG. In this step, the silicon oxide film 8 is formed on the entire surfaces so that the silicon oxide film 8 is formed on the side surfaces of the gate electrodes MG and SG from the state shown in FIGS. 4A and 4B. Etching is performed to expose the upper surfaces of the gate electrodes MG and SG, side surfaces of the gate electrodes SG facing each other, and the gate insulating film 3 of the silicon substrate 2 between the gate electrodes SG-SG.

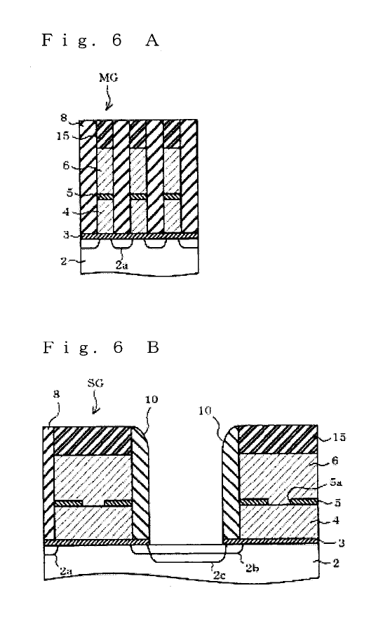

As shown in FIGS. 6A and 6B, the spacer films 10, which are TEOS films as the silicon oxide films, are formed on the side surfaces of the pair of gate electrodes SG facing each other. To form the spacer films 10, the TEOS film of a predetermined thickness is formed on the entire surface and then etched back by the RIE as spacer processing to leave the TEOS films on the side surfaces of the gate electrodes SG. At this time, the gate insulating film 3 exposed between the gate electrodes SG-SG are also removed. Alternatively, the etching may be stopped before removing the gate insulating film 3.

The impurity (e.g., phosphorous or arsenic in the case of n-type) is introduced at a high concentration through ion implantation to the surface of the silicon substrate 2 between the gate electrodes SG-SG by using the spacer films 10 formed of the TEOS films as the masks. The heating is performed to activate the impurity and thus the drain region (source region) 2c for contact is formed, whereby the LDD structure is obtained.

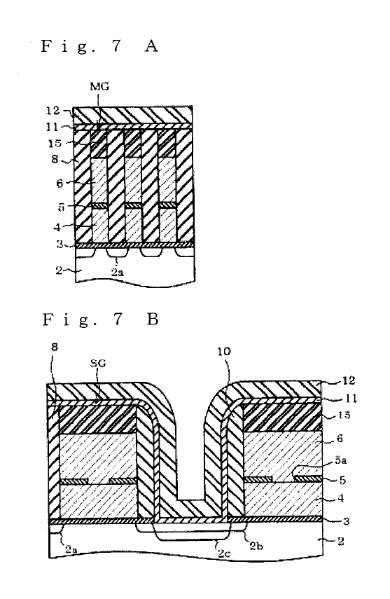

Ts shown in FIGS. 7A and 7B, the silicon oxide film 11 as a liner film having a predetermined thickness is formed to be in contact with the upper surface of the structure, that is, the upper surfaces of the silicon nitride films 15 on the upper surfaces of the gate electrodes MG and SG, the upper surfaces of the silicon oxide films 8 embedded between the gate electrodes, and the surfaces of the spacer films 10 between the gate electrodes SG-SG, and the upper surface of the silicon substrate 2. The silicon nitride film 12 as a liner film having a predetermined thickness is formed on the upper surface of silicon oxide film 11. Thus, between the gate electrodes SG-SG, the silicon oxide film 11 and the silicon nitride film 12 are formed along the surfaces of the spacer films 10 and the surface of the silicon substrate 2, and a recess is formed thereat.

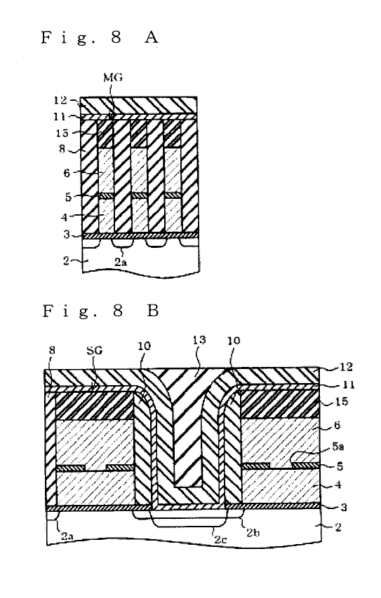

As shown in FIGS. 8A and 8B, the silicon oxide film 13 having high flowability is formed in an embedded manner to bury the recess between the gate electrodes SG-SG. Here, flattening is performed to remove the silicon oxide film 13 not in the recess by grinding through the CMP with the silicon nitride film 12 used as the stopper.

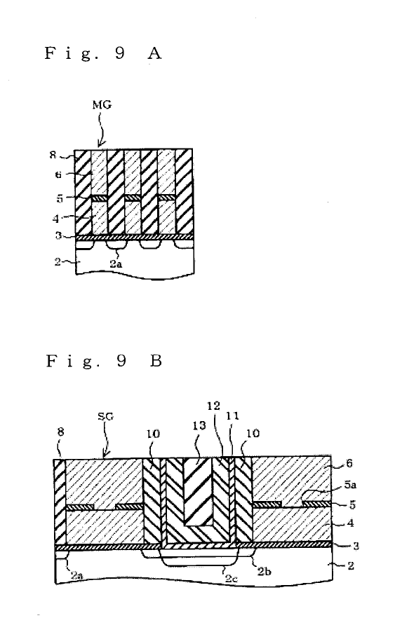

As shown in FIGS. 9A and 9B, etch back for removing the silicon nitride film 15 is performed to form the silicide film 7. At the same time, the silicon oxide films 8, 10, 11, and 13 and the silicon nitride film 12 are also etched back, and thus non-selective etching is performed.

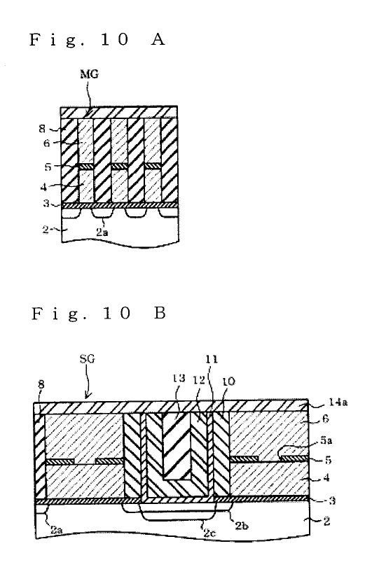

As shown in FIGS. 10A and 10B, a silicon nitride film 14a is formed entirely on the etched back surface. The silicon nitride film 14a serves as the stopper in the RIE for forming a contact in the later step.

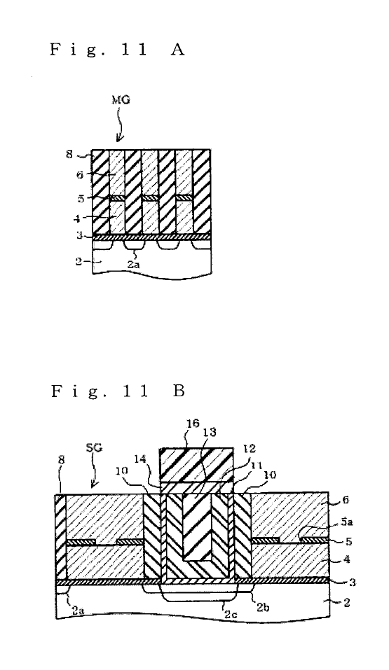

As shown in FIGS. 11A and 11B, a resist films 16 is patterned to cover portions of the silicon nitride film 14a formed as described at the gate electrode SG not being the memory cell and between the gate electrodes of transistors of the peripheral circuit. The etching is performed by using the resist film 16 as a mask to remove the silicon nitride film 14a not at the resist film 16 pattern portions is removed, to thereby form the silicon nitride film 14. Here, the patterning is performed in such a manner that the silicon nitride film 14 covers the portion between the gate electrodes SG-SG more on the inner side than the spacer film 10, more specifically, the upper surfaces of the silicon oxide film 11, the silicon nitride film 12, and the silicon nitride film 13.

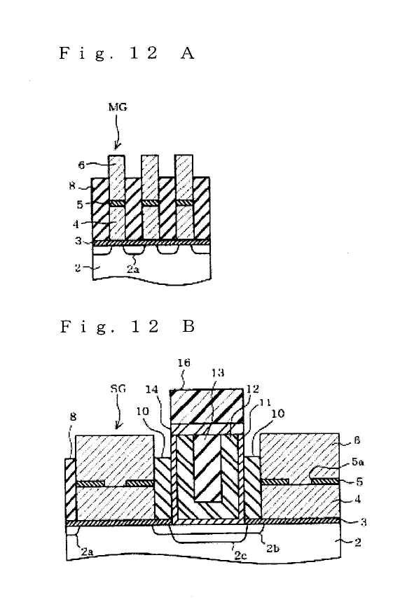

As shown in FIGS. 12A and 12B, the silicon oxide films 8 and the spacer films 10 are etched back by the RIE in such a manner that the polycrystalline silicon films 6 exposed in upper portions of the gate electrodes MG and SG have the upper portions exposed by a predetermined depth. The etch back is performed through highly selective etching on the silicon oxide films with respect to the polycrystalline silicon film 6. The etched back depth is set to be suitable for controlling the amount of silicidation in the later step.

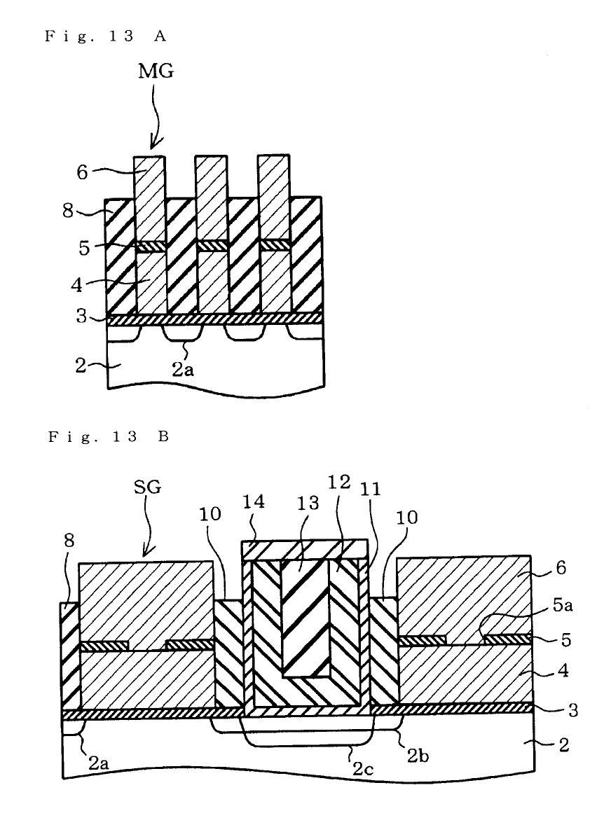

At this stage, the portion between the select gate electrodes SG-SG is covered by the silicon nitride film 14 so as not to be depressed by the etch back processing, whereby a large level difference between the upper surface of the select gate electrodes SG-SG and the upper surfaces of the silicon oxide film 11, the silicon nitride film 12, and the silicon nitride film 13 is not produced. Furthermore, the polycrystalline silicon films 6 suitable for the silicidation in the upper portion of the gate electrode SG has the upper portion exposed. As shown in FIGS. 13A and 13B, the resist film 16 is removed by ashing so that the upper surface of the silicon nitride film 14 is exposed.

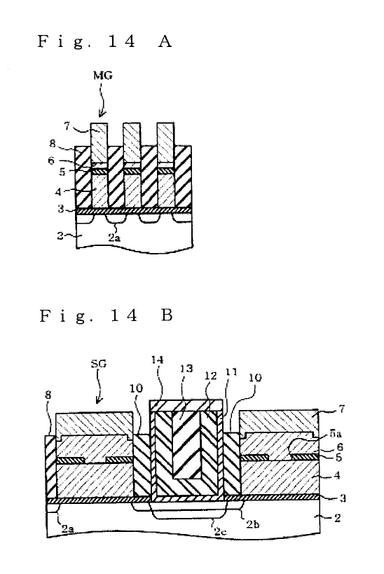

As shown in FIGS. 14A and 14B, preprocessing for metal processing for the silicidation processing is performed and silicide metal is formed into a film of a predetermined thickness by sputtering (or CVD). Here, to form nickel silicide, a nickel (Ni) film is formed. After the nickel film is formed, by performing heating with rapid thermal annealing (RTA) the silicidation reaction is induced at a portion where the polycrystalline silicon film 6 is in contact with nickel. The upper portion of the polycrystalline silicon film 6 is silicided, whereby the silicide film 7 is formed.

After the silicide film 7 is formed, an unnecessary nickel film such as that on the silicon oxide film not contributing to the reaction is detached by using sulfuric acid hydrogen peroxide mixture. At this point, the gate electrode MG of the memory cell transistor Trm has the small width. Thus, the silicidation reaction also progresses laterally toward the inner side in the upper portion of the polycrystalline film 6. Accordingly, a portion of the polycrystalline film 6 lower than the upper surface of the silicon oxide film 8 is silicided, and thus the thick silicide film 7 is formed. The gate electrode SG of the select gate transistor Trs is wider than the gate electrode MG. Thus, while the silicidation reaction progresses laterally therein, the silicide film 7 having only an end portion not including the inner side partially silicided at the portion of the polycrystalline film 6 lower than the upper surface of the silicon oxide film 8 or the spacer film 10 is formed.

As shown in FIGS. 3A and 3B described above, the silicon oxide film 9 for contact forming is formed on the entire surface. Here, through heating, the silicide film 7 expands by silicidation reaction to be taller than the state at which the polycrystalline film 6 is formed, to thereby expand in the upper side and laterally as shown in the figure. Thus, the level of the upper surface of the gate electrodes MG and SG does not reach the level of the level of the upper surface of the silicon nitride film 14 between the gate electrodes SG-SG but becomes slightly higher than the lower surface of the silicon nitride film 14 between the gate electrodes MG and SG. As a result, the level difference D1 is produced. The protrusion 9a with the level difference d smaller than the level difference D1, and thus not large enough to hinder the later steps, is formed on the upper surface of the silicon oxide film 9.

Then, contact holes for forming the bit line contacts CBa and CBb of the memory cell region are formed by photolithography. Here, for forming the contact hole, the silicon oxide film 9 is etched by the RIE. The silicon nitride film 14 can serve as a contact stopper film. By temporary stopping the etching, over or insufficient etching is adjusted. Then, the silicon oxide film 13, the silicon nitride film 12, and the silicon oxide film 11 are sequentially removed by etching, and thus the contact hole is formed.

Next, a thin film of barrier metal such as titanium is formed on an inner wall surface of the contact hole, and a contact material is embedded in the contact hole. Thus, the contact is formed. Thereafter, a multilayer interconnection structure is formed on an upper layer. The manufacturing steps thereafter are not particularly related to the feature of the present invention and thus are not described herein. Thus, the NAND flash memory device 1 is obtained.

In this embodiment, when the upper surface of the polycrystalline silicon film 6 in the upper portion of each of the gate electrodes MG and SG is exposed for the silicidation, the silicon nitride film 14 is formed on the upper surfaces of the silicon oxide films 11 and 13 and the silicon nitride film 12 between the gate electrodes SG-SG so that this is not depressed. Accordingly, the level difference from the gate electrode SG after the silicidation can be made small.

As a result, steps for burying the recess formed by the level difference in the later steps, namely, forming a stopper silicon nitride film, forming an embedded silicon oxide film, and a step for flattening the silicon oxide film by the CMP, needs not to be preformed. Thus, the silicon nitride film can be prevented from having scratches on the surface by the CMP using the silicon nitride film formed at a low temperature after the silicide film 7 is formed as a stopper, whereby the failure due to the scratches can be prevented.

The silicon nitride film 14 is formed on the upper surfaces of the silicon oxide films 11 and 13 and the silicon nitride film 12 between the gate electrodes SG-SG. Thus, the silicon nitride film 14 can be used as an etching stopper when forming the contact hole in the silicon oxide film 9. Accordingly, the etching controllability can be maintained at a high level. The silicon nitride film 14 is formed before the silicide film 7 is formed, and thus can be formed at a high temperature to have a high film quality because of without the limitation of the formation temperature, and thus can exert higher effect as the stopper film for the RIE.

In the structure, the silicon nitride film is also not formed on the gate electrode of the transistor of the peripheral circuit. However, there is no problem in forming a gate contact at the gate electrode, because the silicide film formed therein can secure a sufficiently-high selection ratio of the silicon oxide film thereto.

If a material of the filler between the gate electrodes SG-SG is changed, the selection ratio between the filler and the silicon oxide film formed between two gate electrodes SG-SG or at the periphery changes, and thus a depth of the recess amount changes. Therefore, the adjustment is performed after a processing of the silicidation. Since the silicon nitride film 14 is formed on the portion, there is not etch back the filler and the silicon oxide film formed between two gate electrodes SG-SG or at the periphery changes, and thus it is possible to be performed as a stable process.

### Second Embodiment

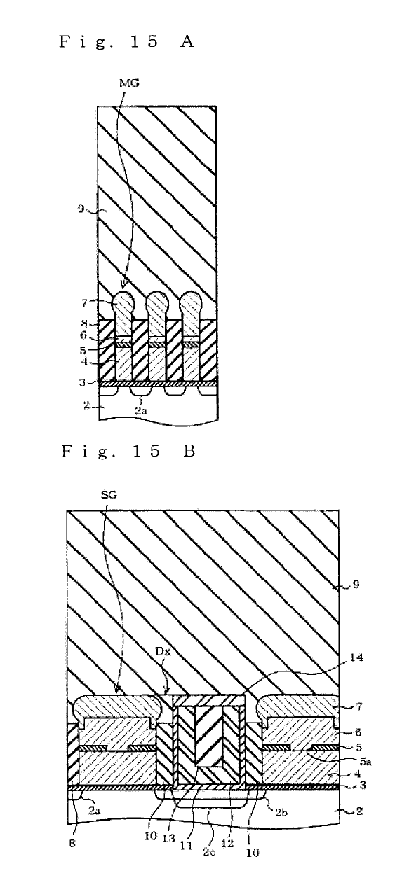

FIG. 15 to FIG. 20 show a second embodiment, and the difference from the first embodiment will be described below. The second embodiment is different from the first embodiment in that substantially eliminating the level difference D1 (portion indicated by the arrow DX) between the silicon nitride film 14 portion between the gate electrodes SG-SG and the gate electrode SG produced in the first embodiment is additionally performed.

The structure shown in FIG. 15 is almost the same as that in the first embodiment, but is different in the point described above. More specifically, in the structure shown in FIG. 15, the height of the gate electrode 15 is the same, but there is a difference that the portion formed of the silicon oxide films 11 and 13 and the silicon nitride film 12 below the silicon nitride film 14 is formed to be lower beforehand to eliminate the level difference D1.

Steps for achieving the above described structure are described below.

The processing as in the first embodiment is performed to obtain the state shown in FIGS. 8A and 8B. The silicon nitride film 15 is etched backed to be removed. At the same time, the silicon oxide films 8, 10, 11, and 13, and the silicon nitride film 12 are also etched back. Thus, non-selective etching is performed to obtain the state shown in FIGS. 9A and 9B.

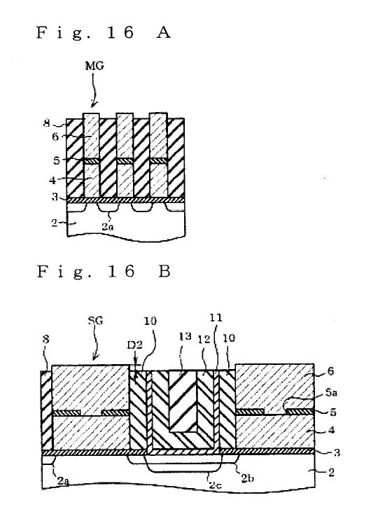

The etching condition is changed so that the silicon oxide films 8, 10, 11, and 13, and the silicon nitride film 12 are selectively etched back with respect to the polycrystalline silicon film 6 in such a manner that the upper surface of the portion other than the polycrystalline silicon film 6 is lower than the upper surface of the polycrystalline silicon film 6 by a depressed amount D2 as shown in FIGS. 16A and 16B. Producing the depression amount D2 is a preparation for eliminating the level difference D1.

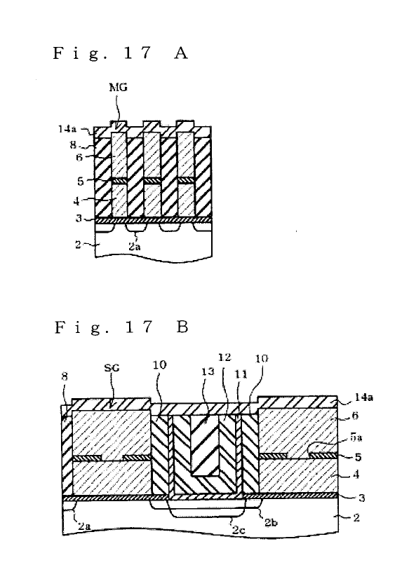

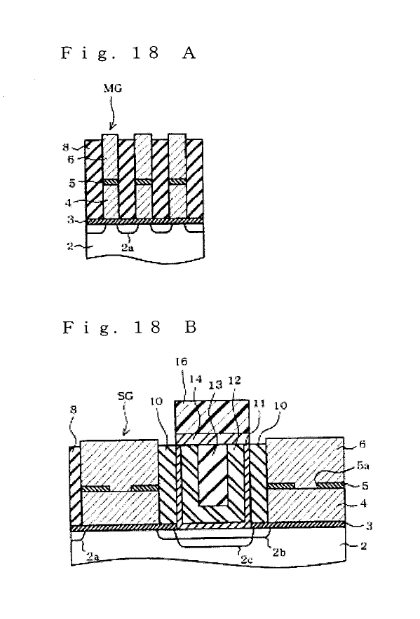

As in the first embodiment, the silicon nitride film 14a is formed entirely on the etched back surface as shown in FIGS. 17A and 17B. As shown in FIGS. 18A and 18B, the resist film 16 is patterned in such a manner that portions of the silicon nitride film 14a formed as described above at the gate electrode SG not in the memory cell and between the gate electrodes of transistors of the peripheral circuit are covered by resist films 16. The etching is performed by using the resist film 16 as a mask to remove the silicon nitride film 14a not at the resist film 16 pattern portions, to thereby form the silicon nitride film 14.

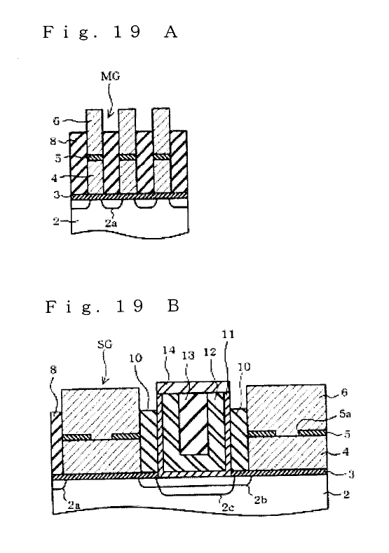

As shown in FIGS. 19A and 19B, the silicon oxide films 8 and the spacer films 10 are etched back in such a manner that the polycrystalline silicon films 6 exposed in the upper portions of the gate electrodes MG and SG have the upper portions exposed by a predetermined depth. The resist film 16 is removed by ashing so that the upper surface of the silicon nitride film 14 is exposed.

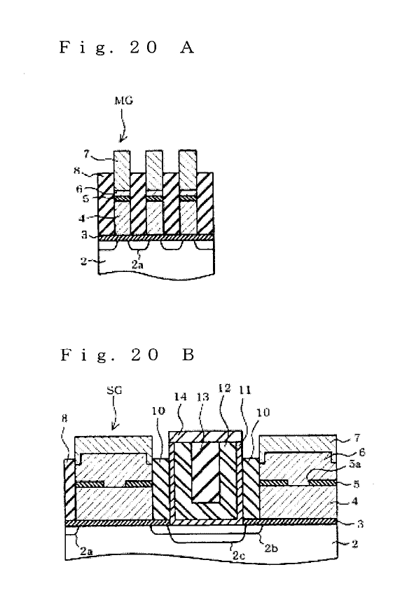

As shown in FIGS. 20A and 20B, preprocessing for metal processing for the silicidation processing is performed and silicide metal is formed into a film of a predetermined thickness by sputtering (or CVD). After the nickel film is formed, by performing heating with the RTA, the upper portion of the polycrystalline silicon film 6 is silicided, whereby the silicide film 7 is formed. After the silicide film 7 is formed, an unnecessary nickel film such as that on the silicon oxide film not contributing to the reaction is detached.

As shown in FIGS. 15A and 15B described above, the silicon oxide film 9 for contact forming is formed on the entire surface. Here, through heating, the silicide film 7 expands by silicidation reaction to be taller than the state at which the polycrystalline film 6 is formed, to thereby expand in the upper side and laterally as shown in the figure. Thus, the level of the upper surface of each of the gate electrodes MG and SG is substantially the same as that of the silicon nitride film 14 between the gate electrodes SG-SG, whereby the level difference is eliminated.

In the second embodiment, the etch back processing for depressing the upper surface between the gate electrodes SG-SG when performing the silicidation is added to the steps in the first embodiment. Thus, depressing in an amount corresponding to the level difference D1 is performed in advance. Accordingly, the level difference D1 produced after the final step in the first embodiment (the structure in FIG. 3) can be eliminated, and thus the silicon oxide film 9 can be prevented from having the protrusion 9a with the level difference d on the upper surface. As a result, a shape with excellent workability can be obtained.

### Third Embodiment

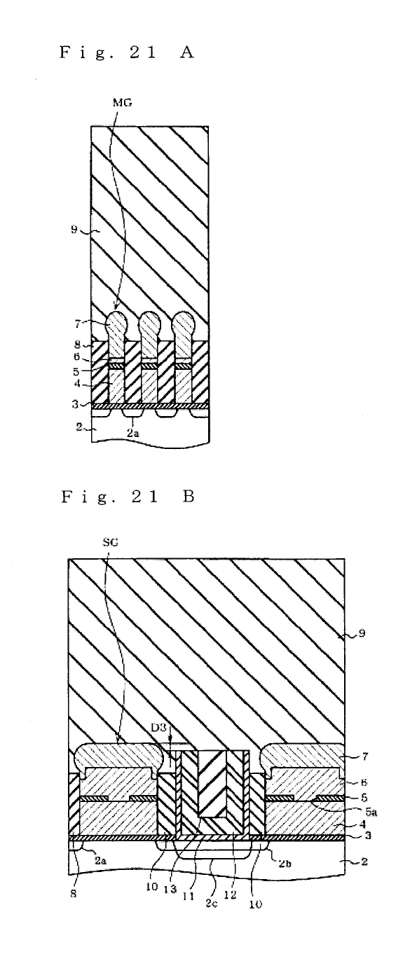

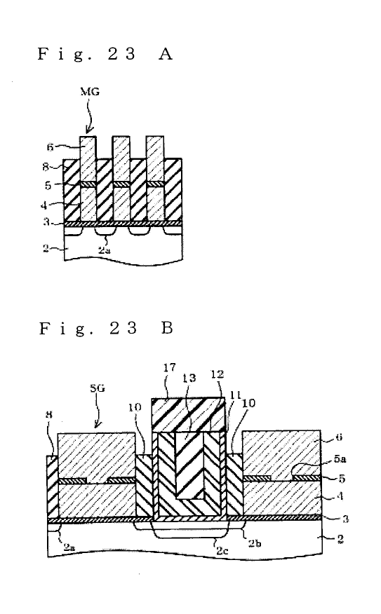

FIG. 21 to FIG. 25 show a third embodiment, and the difference from the first embodiment will be described

FIGS. 21A and 21B show a structure corresponding to the state in FIG. 3 in the first embodiment. The structure shown in FIG. 21 is different from that in FIG. 3A and in that the silicon nitride film 14 is not provided. Thus, the upper surface of the silicide film 7 of the gate electrode SG is slightly higher than the portion formed of the silicon oxide films 11 and 13 and the silicon nitride film 12 between the gate electrodes SG-SG by a level difference D3. The level difference D3 corresponds to the expansion amount of the upper portion of the polycrystalline silicon film 6 being silicided to turn into the silicide film 7. However The level difference D3 is not large enough to produce the level difference in the upper portion of the silicon oxide film 9 formed thereabove, and thus hardly gives any influence.

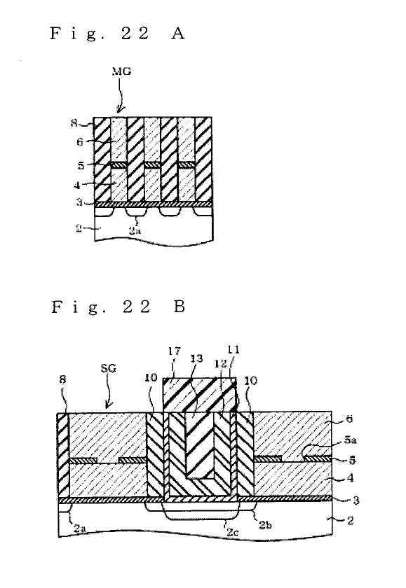

Next, manufacturing steps for achieving the above described structure are described below while focusing on the difference from the first embodiment. The processing as in the first embodiment is performed to obtain the state shown in FIG. 9. As shown in FIGS. 22A and 22B, a resist film 17 patterned to cover the upper surface of the portion formed of the silicon oxide films 11 and 13 and the silicon nitride film 12 exposed between the gate electrodes SG-SG is formed by photolithography.

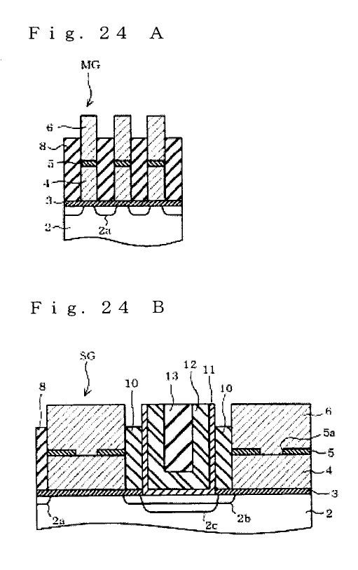

The silicon oxide films 8 and the spacer films 10 are etched back by the RIE to be etched down to a certain depth. Here, the portion formed of the silicon oxide films 11 and 13 and the silicon nitride film 12 covered by the resist film 17 between the selector electrode SG-SG is not etched and thus remains as it is. As shown in FIGS. 24A and 24B, the resist film 17 is removed by ashing and thus the upper surface of the portion formed of the silicon oxide films 11 and 13 and the silicon nitride film 12 is exposed.

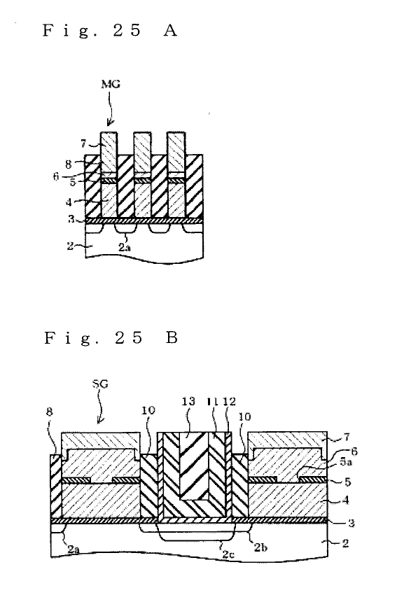

As shown in FIGS. 25A and 25B, preprocessing for metal processing for the silicidation processing is performed and the nickel film as a silicide metal is formed into a film of a predetermined thickness. Then, by performing heating with the RTA the silicidation reaction is induced at a portion where the polycrystalline silicon film 6 is in contact with nickel. Thus, the upper portion of the polycrystalline silicon film 6 is silicided, whereby the silicide film 7 is formed. Then, an unnecessary nickel film such as that on the silicon oxide film not contributing the reaction is detached. Thus, the silicide film 7 is formed in the same state as in the first embodiment.

As shown in FIGS. 21A and 21B described above, the silicon oxide film 9 for contact forming is formed on the entire surface. Here, as described above, through heating, the silicide film 7 expands to be taller than the state at which the polycrystalline film 6 is formed, and thus the upper surface thereof becomes higher than the upper surface of the portion formed of the of the silicon oxide films 11 and 13 and the silicon nitride film 12 by the level difference D3. The level difference D3 is smaller than the level difference D1 in the first embodiment. Thus, the upper surface of the silicon oxide film 9 has almost no protrusion due to the level difference D3.

Then, contact holes for forming the bit line contacts CBa and CBb of the memory cell region are formed by etching the silicon oxide film 9 by photolithography. Since the silicon nitride film 14 serving as the contact stopper film is not formed unlike in the first embodiment, the etching is appropriately performed by controlling the etching amount.

In the third embodiment described above, the silicon oxide films 8 and the spacer films 10 are etched back to be depressed while the portion formed of the silicon oxide films 11 and 13 and the silicon nitride film 12 is covered by the resist film 17 to achieve the structure without the silicon nitride film. Thus, the step of forming the silicon nitride film can be omitted, and the processing with fewer steps than the first embodiment can be achieved. The formation of the contact holes requires accurate etching, but this can be achieved with the excellent controllability of the etching process.

The level difference D3 as shown in FIG. 21 can be substantially eliminated by the following etch back. Specifically, the polycrystalline silicon film 6 is slightly etched down to be lower than the portion formed of the of the silicon oxide films 11 and 13 and the silicon nitride film 12 covered by the resist film 17 when the silicon oxide films 8 and the spacer films 10 are etched back to be depressed while the portion formed of the silicon oxide films 11 and 13 and the silicon nitride film 12 is covered by the resist film 17. Thus, the level of the upper surface of the polycrystalline silicon film 6 can be lowered beforehand. Accordingly, the level difference D3 between the polycrystalline silicon film 6 and the portion can be substantially eliminated in the state where the silicide film 7 is formed.

### Fourth Embodiment

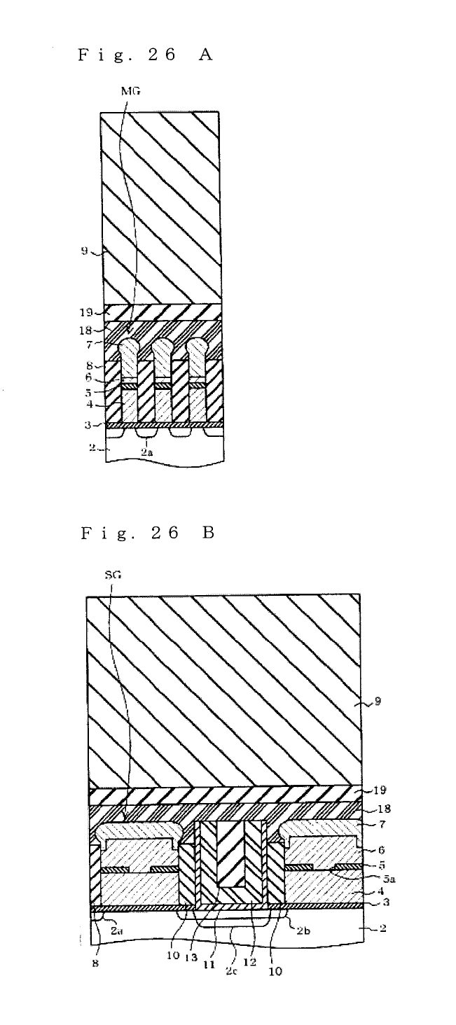

FIG. 26 to FIG. 28 show a third embodiment, and the difference from the third embodiment will be described. Specifically, this embodiment differs from the third embodiment in steps after the silicide film 7 is formed.

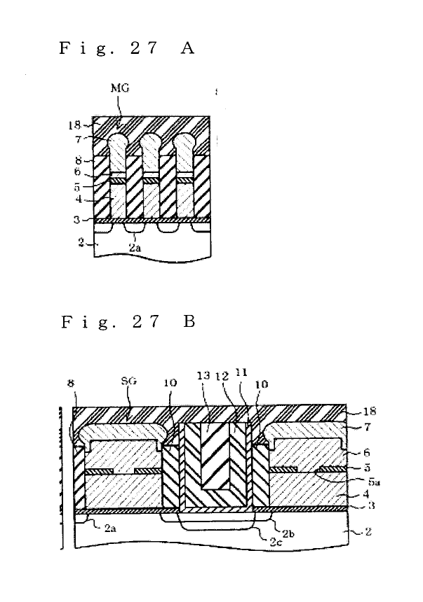

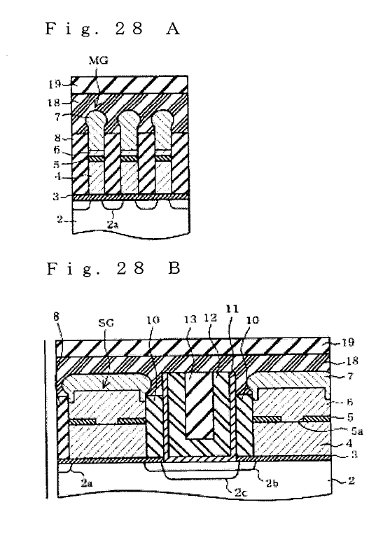

Before obtaining the state where the silicon oxide film 9 is formed as shown in the steps in FIGS. 21A and 21B of the third embodiment, a silicon oxide film 18 having a predetermined thickness is formed as shown in FIGS. 27A and 27B, and then a silicon nitride film 19 having a predetermined thickness is formed as shown in FIGS. 28A and 28B to obtain the structure shown in FIGS. 26A and 26B.

In the fourth embodiment, while obtaining the advantage that the level difference can be eliminated when the silicide film 7 is formed with the steps of the third embodiment, the silicon nitride film 19 is formed on the entire surface and thus, the function of preventing the water and the like from entering from the outside can be provided. Since the silicon nitride film 19 needs not to be patterned and thus, the number of steps does not largely increase.

### Fifth Embodiment

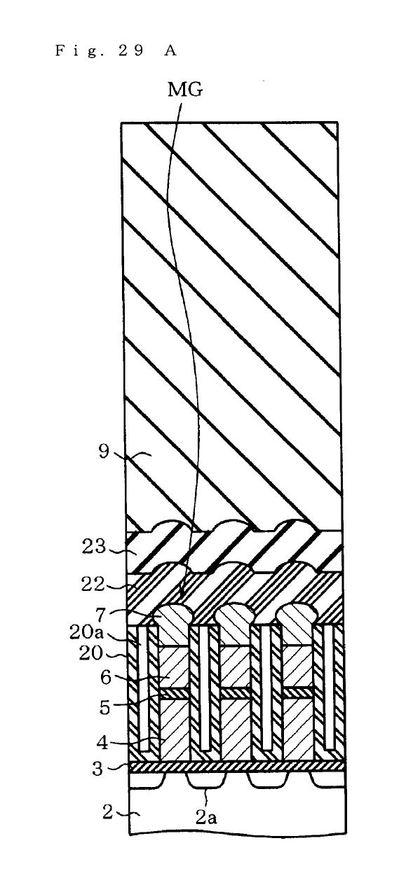

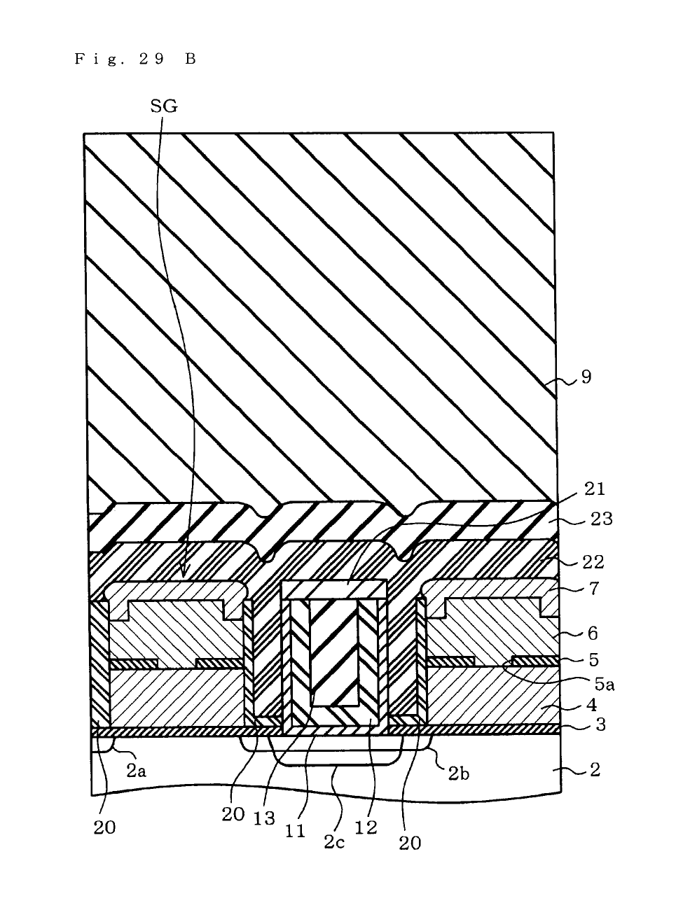

FIG. 29 to FIG. 43 show a fifth embodiment, and the difference from the second embodiment will be described. In the fifth embodiment, instead of providing an insulating film between the gate electrodes MG-MG of the memory cell transistors Trm, an air gap filled with vacuum or air is provided for the insulation.

In FIGS. 29A and 29B, a silicon oxide film 20 having a predetermined thickness is provided from a bottom surface portion to a predetermined height between the side wall surfaces of the gate electrodes MG and SG and the gate insulating film 3 on the upper surface of the silicon substrate 2 between the gate electrodes. Instead of the silicon nitride film 14 in the second embodiment, a silicon oxide film 21 is formed on the upper surface of the portion formed of the silicon oxide films 11 and 13 and the silicon nitride film 12 between the gate electrodes SG-SG.

An air gap 20a of a vacuum state or into which air is introduced is provided on the inner side of the portion between the gate electrodes MG-MG or the gate electrodes MG-SG where the silicon oxide film 20 is formed. The air gap 20a is provided as insulating means instead of an insulating film, and exerts an effect of reducing the floating capacity between the adjacent memory transistors Trm so that operation error caused by the interconnection is less likely to occur.

A silicon oxide film 22 is formed on the portion above the air gap 20a surrounded by the silicon oxide film 20 where the silicide film 7 is exposed and portions between the gate electrodes SG-SG excluding the portion formed of the silicon oxide films 11 and 13 and the silicon nitride film 12. As will be described later, the silicon oxide film 22 is formed under a bad coverage condition of covering the level difference. By forming the silicon oxide film 22, the air gap 20a is formed in the closed portion. A silicon nitride film 23 as a barrier insulating film having a predetermined thickness is formed on an upper surface of the silicon oxide film 22. The silicon oxide film 9 similar to that described above is formed on the upper surface of the silicon nitride film 23.

By providing the air gaps 20a between the gate electrodes MG of the memory transistors Trm as described above, a coupling capacitance can be reduced compared with the case where a space between the cells of the memory transistors Trm is filled with an insulating film such as a silicon oxide film. Thus, possibility of an occurrence of operation error due to the interference of the operations can be reduced as much as possible. Also in this structure, the level difference can be prevented from being produced when the silicide film 7 is formed. Thus, the silicon oxide film for eliminating the level difference and the silicon nitride film serving as the stopper in the CMP need not to be formed.

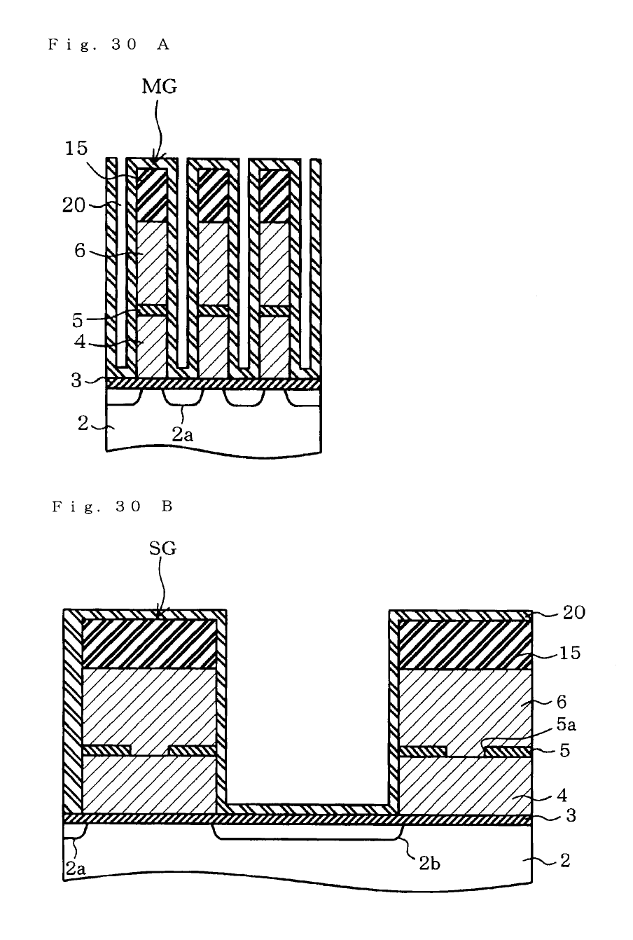

Next, manufacturing steps for achieving the structure is described while focusing on steps different from those in the second embodiment. First, the processing as in the first embodiment is performed to obtain the state shown in FIGS. 4A and 4B. As shown in FIGS. 30A and 30B, the thin silicon oxide film 20 is formed on the side wall portions between the gate electrodes SG-SG and the gate electrodes MG-SG. In the fifth embodiment, the silicon oxide film 20 is formed along the sidewall portions and the bottom surface portion between the gate electrodes MG-MG. At this stage, a gap remains between the gate electrodes MG-MG.

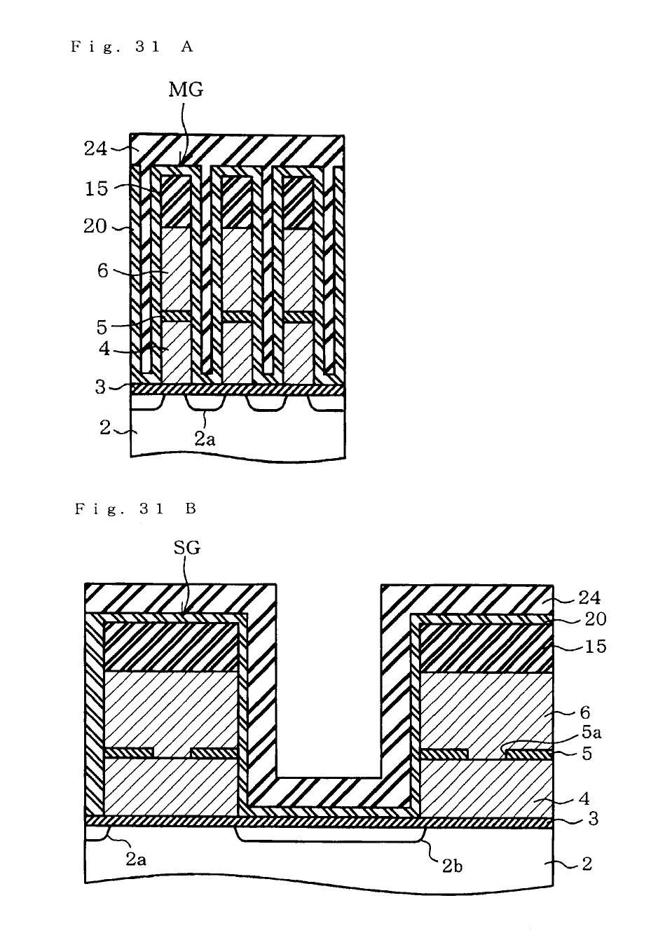

As shown in FIGS. 31A and 31B, a silicon nitride film 24 for spacer forming having a predetermined thickness is formed. The silicon nitride film 24 is formed to bury the gap between the gate electrodes MG-MG and thus also serve as a sacrificial film for forming the air gap 20a.

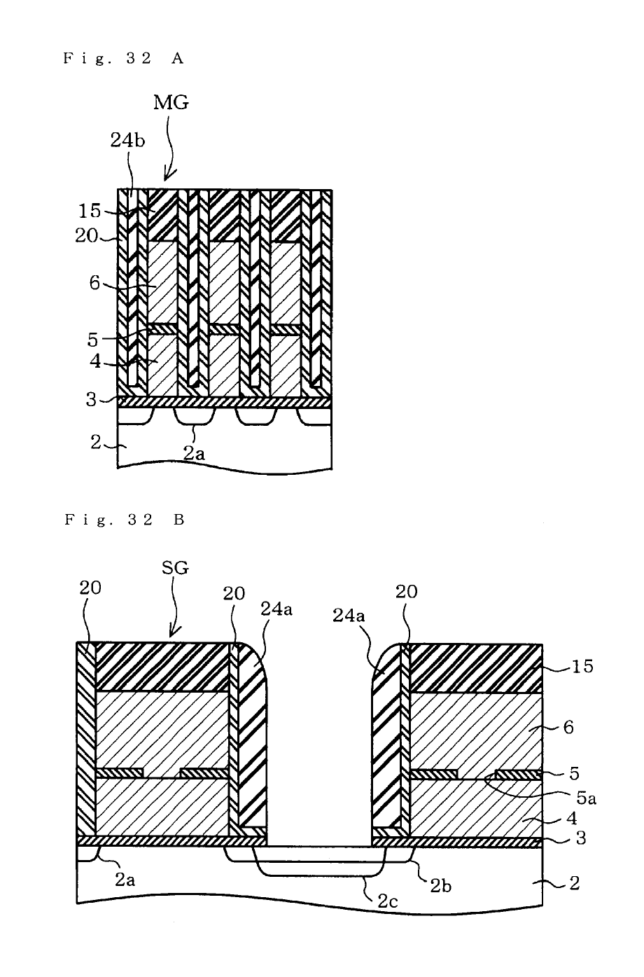

As shown in FIGS. 32A and 32B, a spacer process is performed. Etch back is performed through the RIE, leaving the silicon nitride film 24 on the side wall portion of the gate electrode SG. Thus, a spacer film 24a is formed. At this point, the silicon nitride film 24 filled between the gate electrodes MG-MG remains without being etched back, as a silicon nitride film 24b. At the same time, the gate insulating film 3 exposed between the gate electrodes SG-SG is also removed, but the etching process may also be performed in such a manner that the gate insulating film 3 remains. Next, the impurity is introduced at a high concentration through ion implantation into the surface of the silicon substrate 2 between the gate electrodes SG-SG by using the spacer film 24a as a mask. The heating is performed to activate the impurity and thus the drain region (source region) 2c is formed, whereby the LDD structure is obtained.

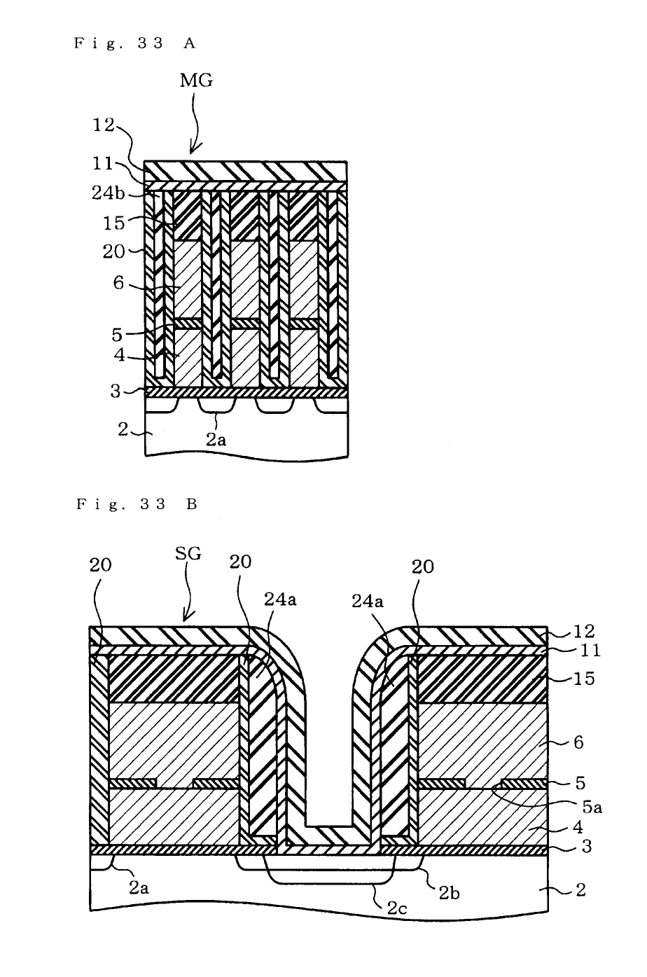

As shown in FIGS. 33A and 33B, the silicon oxide film 11 having a predetermined thickness as a liner film is formed to be in contact with the upper surface of the structure, that is, the upper surfaces of the silicon nitride films 15 that are the upper surfaces of the gate electrodes MG and SG, the upper surfaces of the silicon oxide film 20 and the silicon nitride film 24 embedded between the gate electrodes, the surface of the spacer film 24a between the gate electrodes SG-SG, and the upper surface of the silicon substrate 2. The silicon nitride film 12 having a predetermined thickness as a liner film is formed on the upper surface of the silicon oxide film 11.

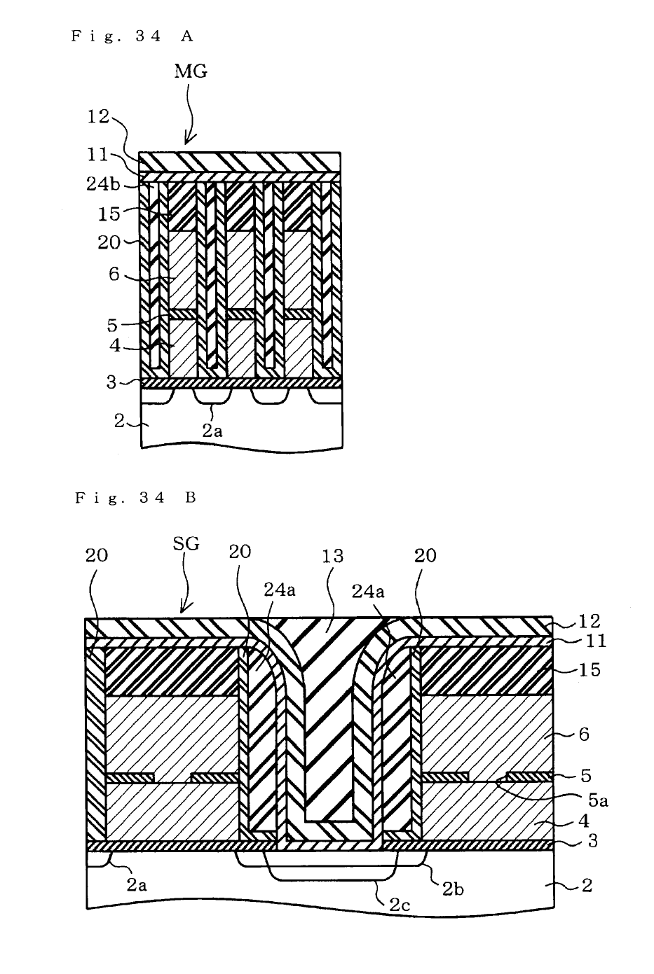

As shown in FIGS. 34A and 34B, the silicon oxide film 13 having high flowability is formed in an embedded manner to bury the recess between the gate electrodes SG-SG. Here, flattening is performed to remove the silicon oxide film 13 not in the recess by grinding through the CMP with the silicon nitride film 12 used as the stopper.

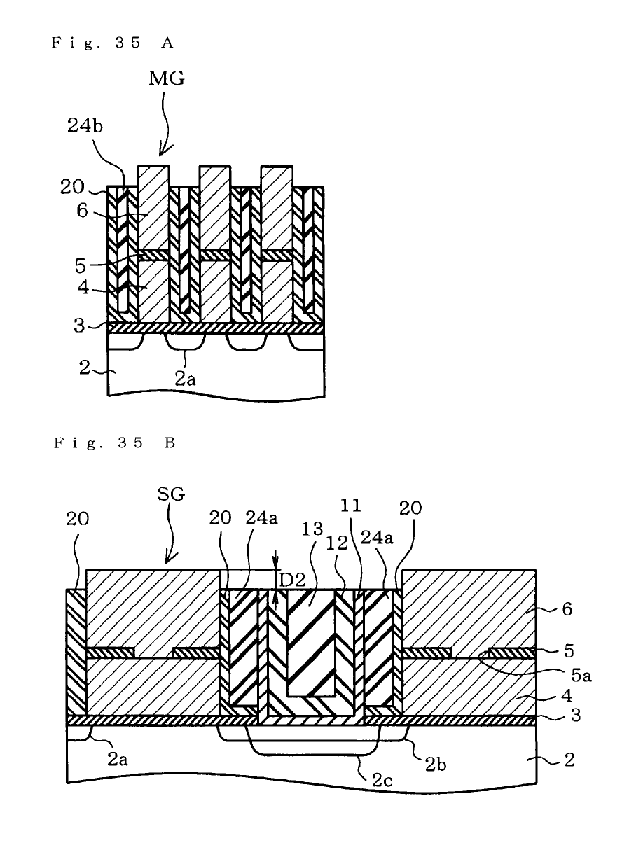

As shown in FIGS. 35A and 35B, etch back for removing the silicon nitride film 15 is performed. At the same time, the silicon oxide films 11, 13, and 20, and the silicon nitride films 12 and 24b are also etched back. Thus, non-selective etching is performed to obtain the state shown in FIGS. 9A and 9B. The etching condition is changed so that the silicon oxide films 11, 13, and 20 and the silicon nitride films 12 and 24b are selectively etched back with respect to the polycrystalline silicon film 6 in such a manner that the upper surface of the portion other than the polycrystalline silicon film 6 becomes lower than the upper surface of the polycrystalline silicon film 6 by the depression amount D2

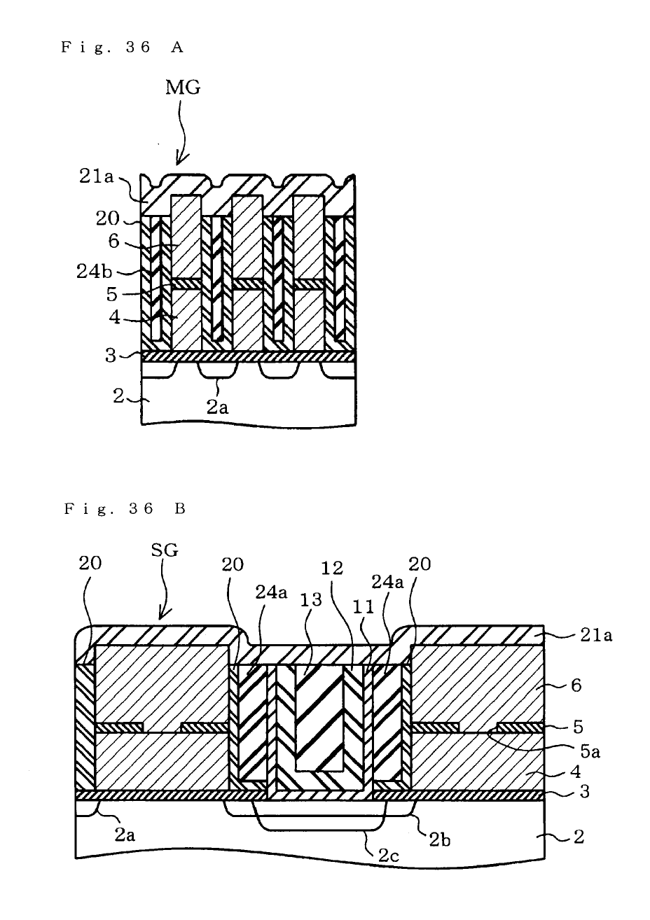

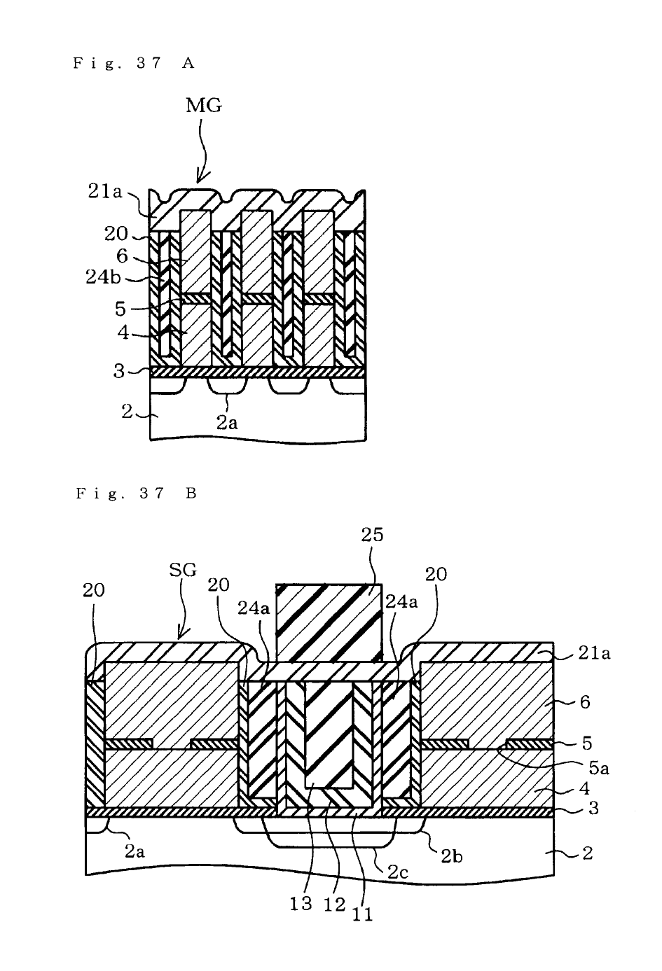

As in the second embodiment, a silicon nitride film 21a is formed entirely on the etched back surface as shown in FIGS. 36A and 36B. As shown in FIGS. 37A and 37B, a resist film 25 is patterned in such a manner as to cover portions of the silicon nitride film 21a formed as described at the gate electrode SG not in the memory cell and between the gate electrodes of transistors of the peripheral circuit.

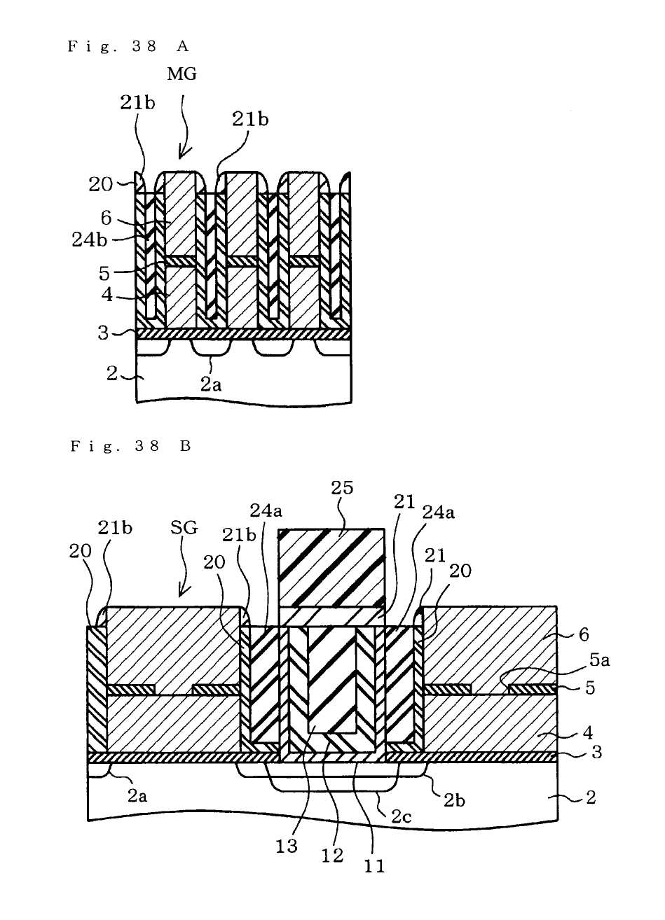

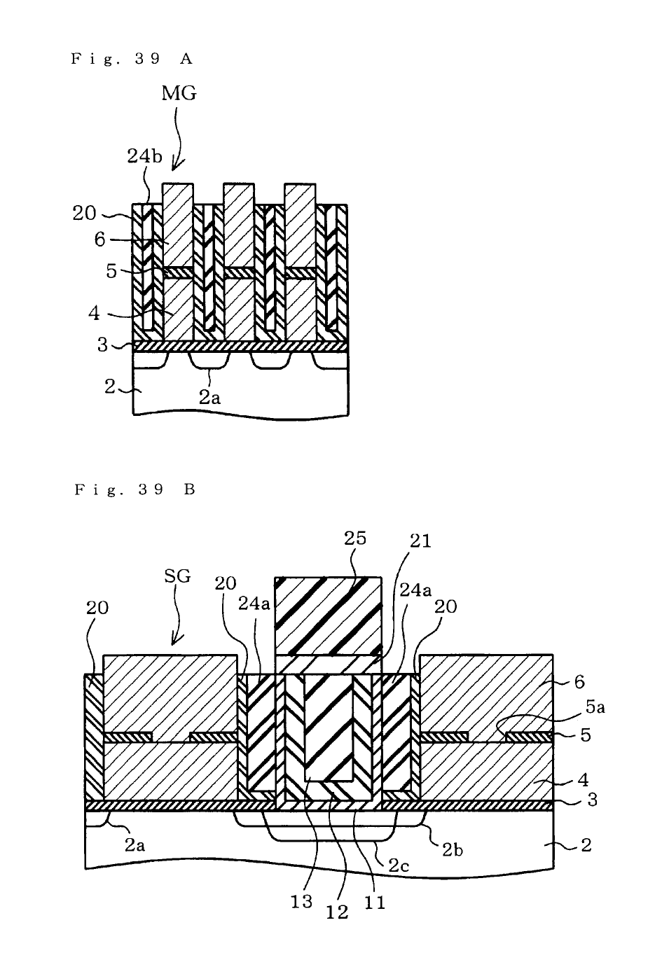

As shown in FIGS. 38A and 38B, the etching is performed by using the resist film 25 as a mask to remove the silicon nitride film 21a not at the resist film 25 pattern portions, to thereby form the silicon nitride film 21. At this stage, the silicon oxide film 21a slightly remains as a silicon oxide film 21b on the side wall portions. A further etching is performed to remove the silicon oxide film 21b as shown in FIGS. 39A and 39B.

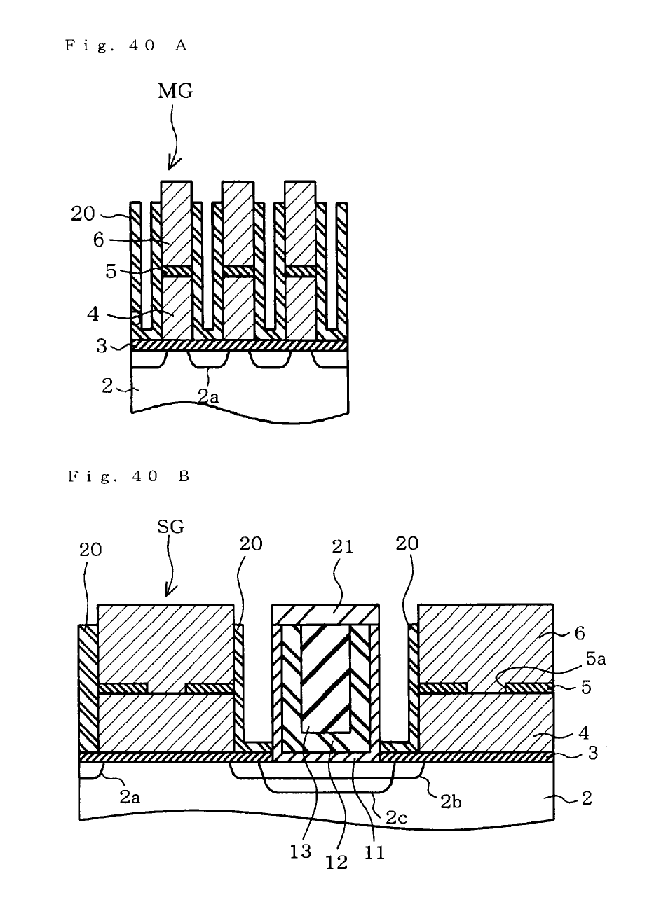

As shown in FIGS. 40A and 40B, the resist film 25 is removed by ashing, and the spacer film 24a and the silicon nitride film 24b is removed by wet etching using phosphoric acid solution with the silicon oxide film 21 serving as a mask.

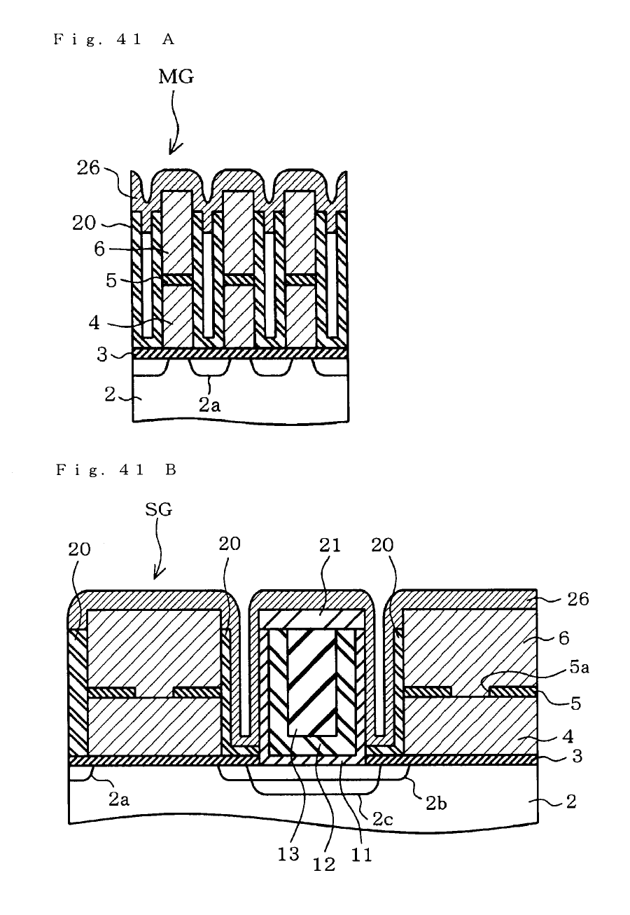

As shown in FIGS. 41A and 41B, the preprocessing for metal processing for the silicidation processing is performed and a nickel film 26 of a predetermined thickness is formed by sputtering.

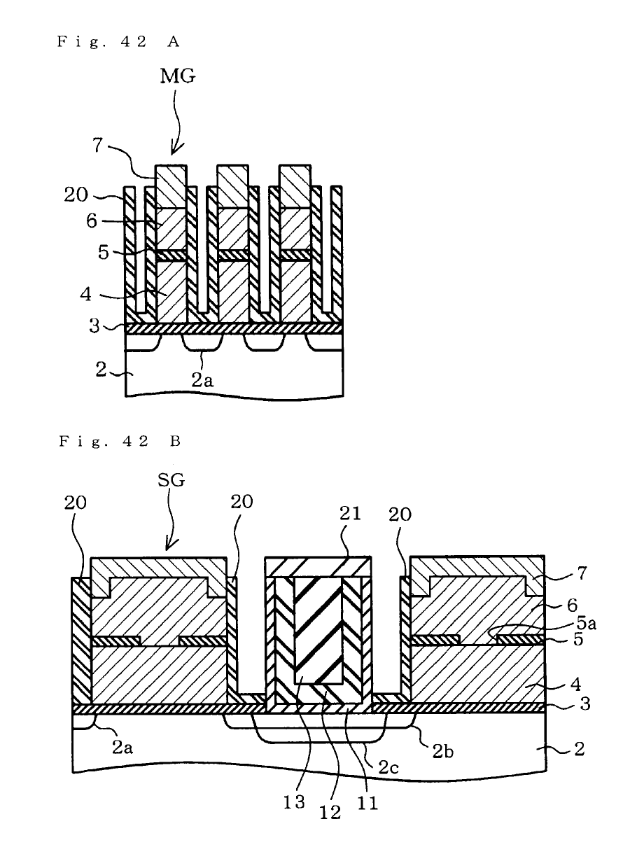

As shown in FIGS. 42A and 42B, after the nickel film 26 is formed, by performing heating with the RTA, the silicidation reaction is induced at a portion where the polycrystalline silicon film 6 is in contact with the nickel so that the upper portion of the polycrystalline silicon 6 is silicided, whereby the silicide film 7 is formed. After the silicide film 7 is formed, an unnecessary nickel film 26 not involved in the reaction is detached by the sulfuric acid hydrogen peroxide mixture.

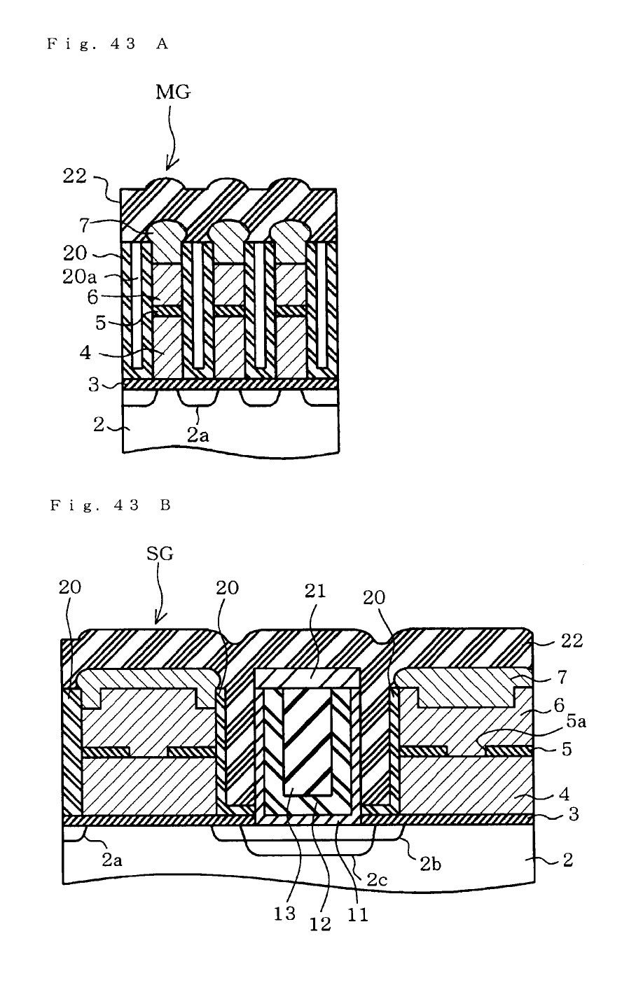

As shown in FIGS. 43A and 43B, the silicon oxide film 22 is formed on the entire surface. Here, the silicon oxide film 22 is formed under a bad step coverage condition by using monosilane gas. Thus, an upper portion of the gap surrounded by the silicon oxide film 20 between the gate electrodes MG-MG is closed.

Thus, the air gap 20a filled with vacuum or air as an insulator is formed at the closed portion. A portion between the gate electrodes SG-SG from which the spacer film 24a is removed is relatively wide. Thus, the silicon oxide film 22 is embedded therein. The height of the portion between the gate electrodes SG-SG in which the silicon oxide film 21 is formed is substantially the same as that of a portion of the gate electrode SG in which the silicide film 7 is formed. Thus, an upper portion of the silicon oxide film 22 is relatively flat.

As shown in FIGS. 29A and 29B, the silicon nitride film 23 having a predetermined thickness as a barrier insulating film is formed on an upper surface of the silicon oxide film 22. The silicon oxide film 9 for contact forming similar to that described above is formed on the resultant structure, and has a substantially flat upper surface.

Then, the contact holes for forming the bit line contacts CBa and CBb of the memory cell region are formed by photolithography as is described above. Here, for forming the contact hole, the silicon oxide film 9 is etched by the RIE. The silicon nitride film 23 as the barrier film can serve as a contact stopper film. By temporary stopping the etching, over or insufficient etching is adjusted. Then, the silicon oxide films 22, 21, and 13, the silicon nitride film 12, and the silicon oxide film 11 are sequentially removed by etching, and thus the contact hole is formed. Then, the contacts are formed by the step described above.

In this embodiment, the processes similar to those in the second embodiment can be employed for the structure in which the air gap 20a is formed. Thus, when the upper surfaces of the polycrystalline silicon films 6 in the upper portions of the gate electrodes MG and SG are exposed for the silicidation, the silicon oxide films 11 and 13 and the silicon nitride film 12 are etched back beforehand to have the upper surface lowered, and the silicon oxide film 21 is formed on the lowered upper surfaces so that the resultant portion substantially the same height as the polycrystalline silicon film 6, whereby the level difference from the gate electrode SG after the silicidation can be substantially eliminated.

Accordingly, in the manufacturing steps for a NAND flash memory device having a structure having the excellent insulation between the gate electrodes MG-MG of the memory cell transistors Trm, the step for burying the recess produced by the level difference is not required and thus the number of steps can be reduced. Since there is no need to perform the burying step, the occurrence of the scratch by performing the CMP can be avoided.

### Other Embodiments

In addition to the above described embodiments, the following modification is possible.

The thicknesses of the silicon nitride film 14 and the silicon oxide film 21 as the adjustment insulating films can be appropriately set in accordance with the formed condition, the thickness, and the like of the silicide film 7. The widths W of the adjustment insulating films can may be larger or smaller than that in the above description. The width of the adjustment insulating film is set within a range not producing a level difference in the silicon oxide film 9 as the inter-layer insulating film formed above, and not hindering the formation of the silicide film 7 of the adjacently disposed gate electrode SG.

In the embodiments described above, the polycrystalline silicon films 4 and 6 are respectively formed as the first and the second silicon films. Instead, initially, an amorphous silicon film may be formed in place of the polycrystalline silicon film. Still, through the later processing steps, the amorphous silicon film is expected to turn into the polycrystalline silicon film at the final stage.

While the silicide film 7 is the nickel silicide film in the above description, the metal for the silicidation may also be cobalt (Co), titanium (Ti), platinum (Pt), palladium (Pd), tantalum (Ta), molybdenum (Mo), and the like.

While the bit contacts CBa and CBb are each disposed close to either of the select gate electrodes SG and SG, so as to be arranged in the zigzag form in the bit line contact formation region in the above description, the bit contacts CBa and CBb may be positioned in the center between the select gate lectrodes SG-SG, and each element region Sa may include one of the bit contacts CBa and CBb.

A BPSG film, a PSG film, an NSG film, and the like may be used instead of the silicon oxide film 11.

The present invention may be applied to a mode where a dummy transistor is provided between the select gate transistor Trs1 and the memory cell transistor Trm.

Instead of the NAND flash memory device 1, the present invention may be applied to other nonvolatile semiconductor storage devices such as a NOR flash memory device and an EEPROM.

The embodiments of the present invention are described above. The embodiments are provided as examples and the scope of the invention is not intended to be limited to the embodiments. The newly provided embodiments can be implemented in various other forms, and can be omitted, replaced, and changed in various ways without departing from the spirit of the present invention. The embodiments and the modifications thereof are included in the scope and the gist of the present invention and are also included in the invention described in the scope of claims and its equivalents.

What is claimed is:

1. A nonvolatile semiconductor storage device manufacturing method comprising:
forming a gate insulating film, a first silicon film, an inter-electrode insulating film, a second silicon film, and a processing insulating film on a semiconductor substrate;
etching the processing insulating film, the second silicon film, the inter-electrode insulating film, and the first silicon film to form gate electrodes of memory cell transistors and selector gate transistors;
embedding an inter-gate insulating film between the gate electrodes of the memory cell transistors and the selector gate transistors;
detaching the processing insulating film to expose an upper surface of the second silicon film, and processing the inter-gate insulating film so that an upper surface of the inter-gate insulating film is substantially at the same level as the upper surface of the second silicon film;
exposing an upper portion of the second silicon film by etching the inter-gate insulating film between the gate electrodes of two adjacent ones of the selector gate transistors down to a first depth while leaving a contact region of a first width between the gate electrodes;
performing silicidation of the upper portion of the second silicon film of each of the gate electrodes; and
forming an inter-layer insulating film after the silicidation.

2. The nonvolatile semiconductor storage device manufacturing method according to claim 1 further comprising forming an adjustment insulating film on an upper surface of the contact region of the first width, after the exposing of the upper portion of the second silicon film by etching of the inter-gate insulating film between the gate electrodes down to the first depth while leaving the contact region of the first width.

3. The nonvolatile semiconductor storage device manufacturing method according to claim 2, wherein the detaching of the processing insulating film to expose the upper surface of the second silicon film, and processing of the inter-gate insulating film so that the upper surface of the inter-gate insulating film is substantially at the same level as the upper surface of the second silicon film includes processing of making the upper surface of the inter-gate insulating film lower than the upper surface of the second silicon film by an adjustment length so that after the silicidation, the upper surface of the second silicon film is at substantially the same level as the upper surface of the processing insulating film.

4. The nonvolatile semiconductor storage device manufacturing method according to claim 3, wherein the adjustment insulating film is formed to have a thickness larger than an increase amount of the thickness of the second silicon film caused by the silicidation.

5. The nonvolatile semiconductor storage device manufacturing method according to claim 1, wherein
the inter-gate insulating film is a silicon oxide film, and
the adjustment insulating film is a silicon nitride film.

6. A nonvolatile semiconductor storage device comprising:
a semiconductor substrate;
gate electrodes of memory cell transistors and selector transistors each including a first silicon film, an inter-electrode insulating film, a second silicon film, and a silicide film which are formed on the semiconductor substrate with a gate insulating film provided in between;
an inter-gate insulating film including
an embedded portion formed to be embedded between the gate electrodes of two selector gate transistors up to a level lower than upper surfaces of the gate electrodes, and
a higher level portion of a first width embedded between the gate electrodes up to substantially the same level with the upper surfaces of the gate electrodes;
an adjustment insulating film formed on an upper surface of the higher level portion of the inter-gate insulating film, wherein
a gap is formed between the gate electrodes of the memory cell transistors.

7. The nonvolatile semiconductor storage device according to claim 6, wherein the inter-gate insulating film of the higher level portion includes a silicon oxide film and a silicon nitride film.

8. The nonvolatile semiconductor storage device according to claim 6, wherein a barrier insulating film is formed on top of the adjustment insulating film.

9. The nonvolatile semiconductor storage device according to claim 6, wherein an upper surface of the inter-gate insulating film between the higher level portion and the gate electrode of the selector gate transistor is recessed.

10. The nonvolatile semiconductor storage device according to claim 6, further comprising, an interlayer insulating film formed above the adjustment insulating film, and an upper surface of the interlayer insulating film is flat.

11. A nonvolatile semiconductor storage device comprising:
a semiconductor substrate;
gate electrodes of memory cell transistors and selector transistors each including a first silicon film, an inter-electrode insulating film, a second silicon film, and a silicide film which are formed on the semiconductor substrate with a gate insulating film provided in between
an inter-gate insulating film including
an embedded portion formed to be embedded between the gate electrodes of two selector gate transistors up to a level lower than upper surfaces of the gate electrodes, and
a higher level portion of a first width embedded between the gate electrodes up to substantially the same level with the upper surfaces of the gate electrodes; and
an adjustment insulating film formed on an upper surface of the higher level portion of the inter-gate insulating film.

12. The nonvolatile semiconductor storage device according to claim 11, wherein an upper surface of the inter-gate insulating film between the higher level portion and the gate electrode of the selector gate transistor is recessed.

13. The nonvolatile semiconductor storage device according to claim 11, wherein the inter-gate insulating film of the higher level portion includes a silicon oxide film and a silicon nitride film.

14. The nonvolatile semiconductor storage device according to claim 11, further comprising, an interlayer insulating film formed above the adjustment insulating film, and an upper surface of the interlayer insulating film is flat.
